(19) United States
(12) Patent Application Publication
(10) Pub. No.: US 2026/0020413 A1
(43) Pub. Date: Jan. 15, 2026

(54) Display Device

(71) Applicant: LG Display Co., Ltd., Seoul (KR)

(72) Inventor: Dohyun Lee, Seoul (KR)

(21) Appl. No.: 19/195,168

(22) Filed: Apr. 30, 2025

(30) Foreign Application Priority Data
Jul. 11, 2024 (KR) 10-2024-0091683

(51) Int. Cl. H10H 29/855; H10H 29/37; H10H 29/85

(52) U.S. Cl. CPC H10H 29/8552; H10H 29/37; H10H 29/8517

(57) ABSTRACT

A display device comprises a substrate, a pixel drive circuit disposed on the substrate, a bank disposed on the pixel drive circuit, a plurality of micro-LEDs disposed on the bank and electrically connected to the pixel drive circuit, a color filter disposed on one of the plurality of micro-LEDs, and a black matrix disposed on another of the plurality of micro-LEDs. Therefore, it is possible to minimize or at least reduce the occurrence of a Mura in accordance with the transfer positions of the plurality of micro-LEDs.

### CROSS-REFERENCE TO RELATED APPLICATION

This application claims the priority of Republic of Korea Patent Application No. 10-2024-0091683 filed on Jul. 11, 2024, which is hereby incorporated by reference in its entirety.

### BACKGROUND

### Field

The present disclosure relates to a display device.

### Description of the Related Art

Display devices are being applied to various electronic devices such as televisions (TVs), mobile phones, notebook computers, and tablet computers.

As the display devices, there are an organic light-emitting display (OLED) configured to autonomously emit, and a liquid crystal display (LCD) that requires a separate light source.

Recently, a display device including a light-emitting diode (LED) has attracted attention as a next-generation display device. Because the light-emitting diode is made of an inorganic material instead of an organic material, the light-emitting diode may be quickly turned on or off, have excellent luminous efficiency, and display high-luminance images in comparison with the liquid crystal display device or the organic light-emitting display device.

### SUMMARY

An object to be achieved by the present disclosure is to provide a display device in which a process of transferring a plurality of micro-LEDs is simplified.

Another object to be achieved by the present disclosure is to provide a display device in which the occurrence of a Mura is reduced.

Objects of the present disclosure are not limited to the aforementioned objects, and other objects, which are not mentioned above, may be clearly understood by those skilled in the art from the following descriptions.

A display device according to an embodiment of the present disclosure comprises a substrate, a pixel drive circuit disposed on the substrate, a bank disposed on the pixel drive circuit, a plurality of micro-LEDs disposed on the bank and electrically connected to the pixel drive circuit, a color filter disposed on one of the plurality of micro-LEDs, and a black matrix disposed on another of the plurality of micro-LEDs. Therefore, it is possible to minimize or at least reduce the occurrence of a Mura in accordance with the transfer positions of the plurality of micro-LEDs.

A display device according to another embodiment of the present disclosure comprises an anode electrode, a first semiconductor layer disposed on the anode electrode, an active layer disposed on the first semiconductor layer, a second semiconductor layer disposed on the active layer, and a cathode electrode disposed on the second semiconductor layer. Therefore, it is possible to uniformly maintain luminance for each pixel even though some of the plurality of micro-LEDs are defective.

A display device according to a yet embodiment of the present disclosure includes a substrate comprising a display area comprising a plurality of subpixels, and one or more non-display areas; a pixel drive circuit disposed on the substrate; a plurality of insulation layers disposed on the pixel drive circuit; a plurality of banks disposed on the plurality of insulation layers; a plurality of micro-LEDs disposed on the plurality of banks and configured to emit white light; a plurality of color filters disposed on the micro-LED in a first group among the plurality of micro-LEDs; and a black matrix disposed on the micro-LED in a second group among the plurality of micro-LEDs.

Other detailed matters of the exemplary embodiments are included in the detailed description and the drawings.

According to the present disclosure, it is possible to simplify the process of transferring the micro-LED by unifying the types of micro-LEDs and reduce production energy by optimizing the above-mentioned process.

According to the present disclosure, the color filter may be disposed on the plurality of micro-LEDs, thereby minimizing or at least reducing the occurrence of a Mura caused by a difference in transfer positions between the plurality of micro-LEDs.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of a display device according to an embodiment of the present disclosure;

FIG. 2 is a top plan view of the display device according to the embodiment of the present disclosure;

FIG. 3 is an enlarged view of the display device according to the embodiment of the present disclosure;

FIG. 4 is a view illustrating a circuit structure according to the embodiment of the present disclosure;

FIGS. 5 to 9 are top plan views of the display device according to the embodiment of the present disclosure;

FIGS. 10 to 13 are cross-sectional views of the display device according to the embodiment of the present disclosure;

FIG. 14 is a top plan view of a display device according to another embodiment of the present disclosure; and

FIGS. 15 to 18 are views illustrating devices to which the display device according to the embodiments of the present disclosure are applied.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

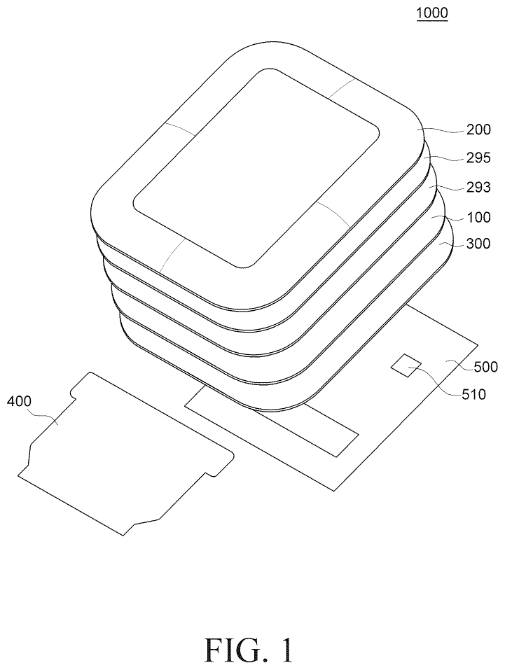

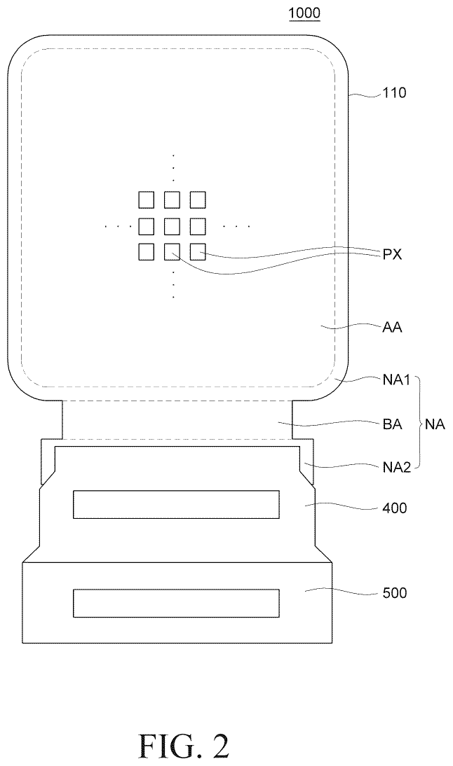

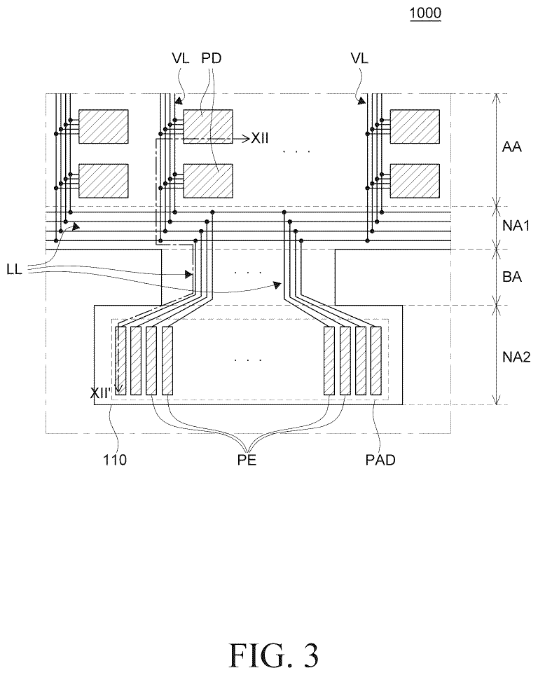

FIG. 1 is a perspective view illustrating a display device according to an embodiment of the present disclosure. FIG. 2 is a top plan view of the display device according to the embodiment of the present disclosure. FIG. 3 is an enlarged view of the display device according to the embodiment of the present disclosure.

With reference to FIGS. 1 to 3, a display device 1000 according to an embodiment of the present disclosure may include a display panel 100, a polarizing layer 293, a bonding layer 295, a cover member 200, a support substrate 300, a flexible circuit board 400, and a printed circuit board 500.

For example, the display panel 100 of the display device 1000 may include a substrate 110. The substrate 110 may be a member configured to support other constituent elements of the display device 1000. The substrate 110 may be made of an insulating material. For example, the substrate 110 may be made of glass, resin, or the like. In addition, the substrate 110 may be made of a material having flexibility. For example, the substrate 110 may be made of a plastic material, such as polyimide (PI), having flexibility. However, the embodiments of the present disclosure are not limited thereto.

The display panel 100 may implement information, videos, and/or images to be provided to a user. For example, the display panel 100 may include a display area AA and a non-display area NA. For example, the substrate 110 may include the display area AA and the non-display area NA. The display area AA and the non-display area NA may not be described as being limited to the substrate 110, but the display area AA and the non-display area NA may be described for the entire display device 1000.

The display area AA may be an area in which images are displayed. The display area AA may include a plurality of pixels PX. The plurality of pixels PX may each include a plurality of subpixels. A plurality of micro-LEDs may be respectively disposed in the plurality of subpixels. Therefore, the display device 1000 according to the embodiment of the present disclosure may be an inorganic light-emitting display device.

The non-display area NA may be an area in which no image is displayed. Various lines and circuits for operating the plurality of pixels PX in the display area AA may be disposed in the non-display area NA. For example, various types of lines and drive circuits may be mounted in the non-display area NA, and a pad part PAD, to which an integrated circuit, a printed circuit, and the like are connected, may be disposed. However, the embodiments of the present disclosure are not limited thereto.

For example, the drive circuits may be a data drive circuit and/or a gate drive circuit. However, the embodiments of the present disclosure are not limited thereto. Lines for supplying control signals for controlling the drive circuits may be disposed. For example, the control signals may include various types of timing signals including clock signals, input data enable signals, and synchronizing signals. However, the embodiments of the present disclosure are not limited thereto. The control signal may be received through the pad part PAD. For example, link lines LL for transmitting signals may be disposed in the non-display area NA. For example, drive components, such as the flexible circuit board 400 and the printed circuit board 500, may be connected to the pad part PAD.

According to the embodiment of the present disclosure, the non-display area NA may include a first non-display area NA1, a bending area BA, and a second non-display area NA2. For example, the first non-display area NA1 may be an area that surrounds at least a part of the display area AA. The bending area BA may be a bendable area extending from at least any one of a plurality of sides of the first non-display area NA1. The second non-display area NA2 may be an area extending from the bending area BA, and the pad part PAD may be disposed in the second non-display area NA2. For example, the bending area BA may be in a curved state, and the remaining area of the substrate 110, except for the bending area BA, may be in a flat state. In this case, as the bending area BA is curved, the second non-display area NA2 may be positioned on a rear surface of the display area AA. However, the embodiments of the present disclosure are not limited thereto.

The display area AA of the substrate 110 or the display device 1000 may have various shapes in accordance with the design of the display device 1000. For example, the display area AA may have a rectangular shape with four corners formed in a round shape. However, the embodiments of the present disclosure are not limited thereto. In another example, the display area AA may have a circular shape or a rectangular shape with four corners formed in a right angle shape. However, the embodiments of the present disclosure are not limited thereto.

According to the embodiment of the present disclosure, a width of the second non-display area NA2 in which a plurality of pad electrodes PE is disposed may be larger than a width of the bending area BA in which only the plurality of link lines LL is disposed. In addition, a width of the display area AA in which the plurality of subpixels is disposed may be larger than a width of the bending area BA in which the plurality of link lines LL are disposed. The drawing illustrates that the width of the bending area BA may be smaller than a width of another area of the substrate 110. However, the shape of the substrate 110 including the bending area BA is illustrative, and the embodiments of the present disclosure are not limited thereto.

With reference to FIG. 3, a plurality of pixel drive circuits PD may be disposed in the display area AA. The plurality of pixel drive circuits PD may be circuits for operating the micro-LEDs of the plurality of subpixels. The plurality of pixel drive circuits PD may each include a plurality of transistors including a driving transistor, and a plurality of storage capacitors. The plurality of pixel drive circuits PD may control light-emitting operations of the plurality of micro-LEDs by supplying control signals, power, and drive currents to the micro-LEDs of the plurality of subpixels. For example, the pixel drive circuit PD may include a power line, and a signal line for controlling light-emitting on/off operations and/or light emission time of the micro-LED. For example, the plurality of pixel drive circuits PD may be operation drivers manufactured on a semiconductor substrate by using a metal-oxide-silicon field effect transistor (MOSFET) manufacturing process. However, the embodiments of the present disclosure are not limited thereto. The operation driver may include the plurality of pixel drive circuits PD and operate the plurality of subpixels.

With reference to FIG. 2 together, the flexible circuit board 400 and the printed circuit board 500 may be disposed below the display panel 100. The flexible circuit board 400 and the printed circuit board 500 may be disposed at least at one side edge of the display panel 100. However, the embodiments of the present disclosure are not limited thereto. One side of the flexible circuit board 400 may be attached to the display panel 100, and another side of the flexible circuit board 400 may be attached to the printed circuit board 500. However, the embodiments of the present disclosure are not limited thereto. The flexible circuit board 400 may be a flexible film. However, the embodiments of the present disclosure are not limited thereto.

The pad part PAD including the plurality of pad electrodes PE may be disposed in the second non-display area NA2. The drive components including one or more flexible circuit boards (or flexible films) 400 and the printed circuit board 500 may be attached or bonded to the pad part PAD. The plurality of pad electrodes PE of the pad part PAD may be electrically connected to one or more flexible circuit boards (or flexible films) 400 and transmit various types of signals (or power) to the plurality of pixel drive circuits PD in the display area AA from the printed circuit board 500 and the flexible circuit board (or flexible film) 400.

The flexible circuit board (or flexible film) 400 may be a film having various types of components disposed on a base film having flexibility. For example, a drive integrated circuit (IC), such as a gate driver IC or a data driver IC, may be disposed on the flexible circuit board (or flexible film) 400. However, the embodiments of the present disclosure are not limited thereto. The drive IC may be a component configured to process data and driving signals for displaying images. The drive IC may be disposed in ways such as a chip-on-glass (COG) method, a chip-on-film (COF) method, or a tape carrier package (TCP) method depending on how the drive IC is mounted. However, the embodiments of the present disclosure are not limited thereto. The flexible circuit board (or flexible film) 400 may be attached or bonded to the plurality of pad electrodes PE by means of a conductive bonding layer. However, the embodiments of the present disclosure are not limited thereto.

The printed circuit board 500 may be a component electrically connected to one or more flexible circuit boards (or flexible films) 400 and configured to supply a signal to the drive IC. The printed circuit board 500 may be disposed at one side of the flexible circuit board (or flexible film) 400 and electrically connected to the flexible circuit board (or flexible film) 400. Various types of components for supplying various signals to the drive IC may be disposed on the printed circuit board 500. For example, various components, such as a timing controller, a power source, a memory, or a processor, may be disposed on the printed circuit board 500. For example, the printed circuit board 500 may include a power management integrated circuit (PMIC). However, the embodiments of the present disclosure are not limited thereto.

The printed circuit board 500 may include at least one hole 510. However, the embodiments of the present disclosure are not limited thereto. Internal components may be disposed in an area corresponding to at least one hole 510 and detect ambient light, a temperature, or the like that may be provided to the plurality of sensors. For example, the internal components may include an ambient light sensor (ALS), a temperature sensor, or the like. However, the embodiments of the present disclosure are not limited thereto. For example, the hole 510 may be a transmission hole or the like. However, the embodiments of the present disclosure are not limited thereto.

With reference to FIG. 1, the polarizing layer 293 may be disposed on the display panel 100. The polarizing layer 293 may suppress or reduce a situation in which light generated from the external light source is introduced into the display panel 100 and affects the micro-LED or the like.

The cover member 200 may be disposed on the polarizing layer 293. The cover member 200 may be a member for protecting the display panel 100. The bonding layer 295 may be disposed between the polarizing layer 293 and the cover member 200. The cover member 200 may be attached to the display panel 100 by using the bonding layer 295. The bonding layer 295 may include an optically clear adhesive (OCA), an optically clear resin (OCR), a pressure-sensitive adhesive (PSA), or the like. However, the embodiments of the present disclosure are not limited thereto.

The support substrate 300 may be disposed between the display panel 100 and the printed circuit board 500. The support substrate 300 may reinforce the rigidity of the display panel 100. The support substrate 300 may be a backplate. However, the embodiments of the present disclosure are not limited thereto.

With reference to FIGS. 1 to 3, the plurality of link lines LL may be disposed in the non-display area NA. The plurality of link lines LL may be lines configured to transmit various types of signals to the display area AA from one or more flexible circuit boards (or flexible films) 400 and the printed circuit board 500. The plurality of link lines LL may extend from the plurality of pad electrodes PE of the second non-display area NA2 toward the bending area BA and the first non-display area NA1 and be electrically connected to a plurality of drive lines VL in the display area AA. The plurality of pixel drive circuits PD may operate by receiving signals from one or more flexible circuit boards (or flexible films) 400 and the printed circuit board 500 through the drive lines VL in the display area AA and the link lines LL in the non-display area NA.

For example, the plurality of drive lines VL may be lines configured to transmit signals, which are outputted from the flexible circuit board (or flexible film) 400 and the printed circuit board 500, to the plurality of pixel drive circuits PD together with the plurality of link lines LL. The plurality of drive lines VL may be disposed in the display area AA and respectively electrically connected to the plurality of pixel drive circuits PD. The plurality of drive lines VL may extend from the display area AA toward the non-display area NA and be electrically connected to the plurality of link lines LL. Therefore, the signals outputted from the flexible circuit board (or flexible film) 400 and the printed circuit board 500 may be transmitted to the plurality of pixel drive circuits PD through the plurality of link lines LL and the plurality of drive lines VL.

When the bending area BA is bent, the plurality of link lines LL may also be partially bent. Stress may be concentrated on a part of the bent link line LL, and therefore, the link line LL may crack. Therefore, the plurality of link lines LL may be made of an electrically conductive material that is excellent in flexibility in order to reduce the occurrence of a crack when the bending area BA is bent. For example, the plurality of link lines LL may be made of an electrically conductive material, such as gold (Au), silver (Ag), or aluminum (Al), that is excellent in flexibility. However, the embodiments of the present disclosure are not limited thereto. In addition, the plurality of link lines LL may be made of one of various electrically conductive materials used for the display area AA. For example, the plurality of link lines LL may be made of molybdenum (Mo), chromium (Cr), titanium (Ti), nickel (Ni), neodymium (Nd), copper (Cu), and an alloy of silver (Ag) and magnesium (Mg), or an alloy thereof. However, the embodiments of the present disclosure are not limited thereto. The plurality of link lines LL may have a multilayer structure including various electrically conductive material. For example, the plurality of link lines LL may have a triple layer structure made of titanium (Ti), aluminum (Al), and titanium (Ti). However, the embodiments of the present disclosure are not limited thereto.

The plurality of link lines LL may have various shapes to reduce stress. At least a part of each of the plurality of link lines LL disposed in the bending area BA may extend in a direction identical to an extension direction of the bending area BA or extend in a direction different from the extension direction of the bending area BA to reduce stress. For example, in case that the bending area BA extends in one direction from the first non-display area NA1 toward the second non-display area NA2, at least a part of the link line LL disposed in the bending area BA may extend in a direction inclined with respect to the direction in which the bending area BA extends. In another example, at least a part of each of the plurality of link lines LL may have patterns with various shapes. For example, at least a part of each of the plurality of link lines LL disposed in the bending area BA may have a shape in which conductive patterns are repeatedly disposed and have at least one of a diamond shape, a rhombic shape, a trapezoidal wave shape, a triangular wave shape, a serrated wave shape, a sine wave shape, a circular shape, and an omega (λ) shape. However, the embodiments of the present disclosure are not limited thereto. Therefore, in order to minimize stress concentrated on the plurality of link lines LL and minimize the occurrence of a crack caused by the stress, the plurality of link lines LL may have various shapes including the above-mentioned shapes. However, the embodiments of the present disclosure are not limited thereto.

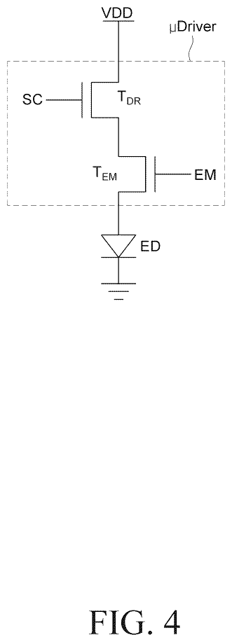

FIG. 4 is a view illustrating a circuit structure according to an embodiment of the present disclosure.

The pixel drive circuit PD may include a micro-driver μDriver. A micro-LED ED may be electrically connected to the micro-driver μDriver of the pixel drive circuit PD and operated. FIG. 4 illustrates that one micro-LED ED is connected to the micro-driver μDriver. However, the present disclosure is not limited thereto. For example, eight micro-LEDs ED may be connected to one micro-driver μDriver. In another example, sixteen micro-LEDs ED may be connected to one micro-driver μDriver, or thirty-two micro-LEDs ED or sixty-four micro-LEDs ED may be simultaneously connected to one micro-driver μDriver. The micro-LED ED may be a micro micro-LED (LED).

One micro-driver μDriver may include a driving transistor T_{DR} and a light-emitting transistor TEM. However, the embodiments of the present disclosure are not limited thereto.

For example, a high-potential power voltage VDD may be applied to a first electrode of the driving transistor T_{DR}, a first electrode of the light-emitting transistor TEM may be connected to a second electrode of the driving transistor T_{DR}, and a scan signal SC may be applied to a gate electrode of the driving transistor T_{DR}. The scan signal SC applied to the gate electrode of the driving transistor T_{DR} may be direct current power, and a fixed reference voltage may be applied for each frame. However, the embodiments of the present disclosure are not limited thereto.

The second electrode of the driving transistor T_{DR} may be connected to the first electrode of the light-emitting transistor T_{EM}, the micro-LED ED may be connected to a second electrode of the light-emitting transistor T_{EM}, and a light emission signal EM may be applied to a gate electrode of the light-emitting transistor T_{EM}. The light emission signal EM applied to the gate electrode of the light-emitting transistor T_{EM} may be a pulse width modulation signal that changes for each frame. However, the embodiments of the present disclosure are not limited thereto.

A first electrode of the micro-LED ED may be connected to the second electrode of the light-emitting transistor T_{EM}, and a second electrode of the micro-LED ED may be connected to the ground. For example, the first electrode may be an anode electrode, and the second electrode may be a cathode electrode. However, the embodiments of the present disclosure are not limited thereto.

The driving transistor T_{DR} and the light-emitting transistor T_{EM} may each be an n-type transistor or a p-type transistor.

The driving transistor T_{DR} may be turned on by the scan signal SC applied from the timing controller to the micro-driver μDriver, and the light-emitting transistor T_{EM} may be turned on by the light emission signal EM. Therefore, the drive current is applied to the micro-LED ED via the driving transistor T_{DR} and the light-emitting transistor T_{EM} by the high-potential power voltage VDD applied to the first electrode of the driving transistor T_{DR}, such that the micro-LED ED may emit light.

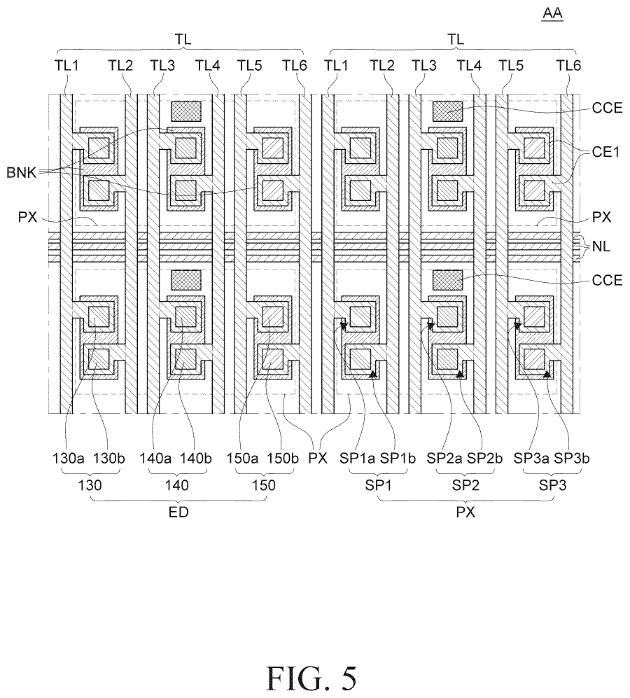

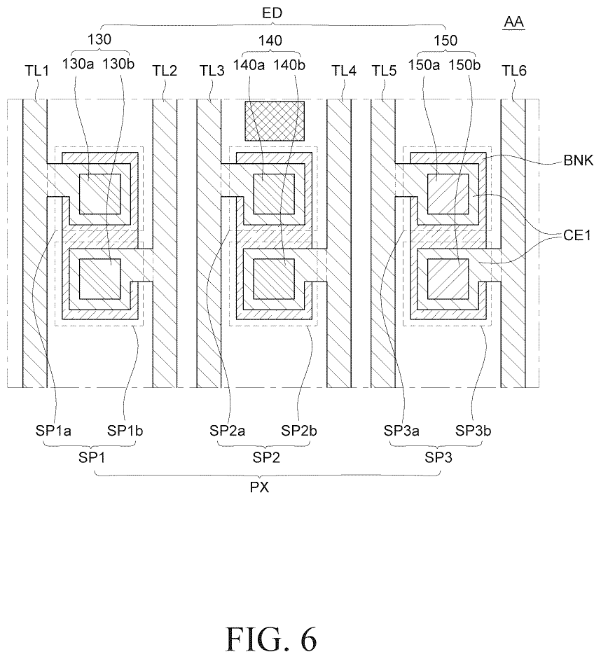

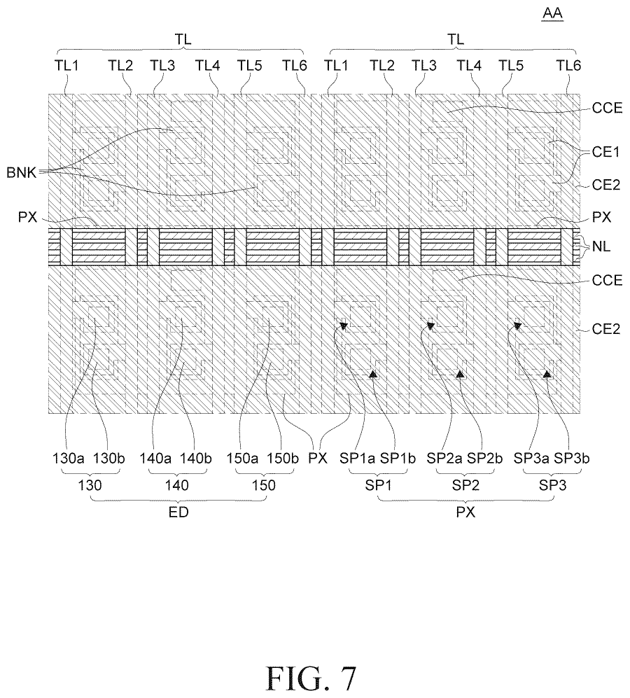

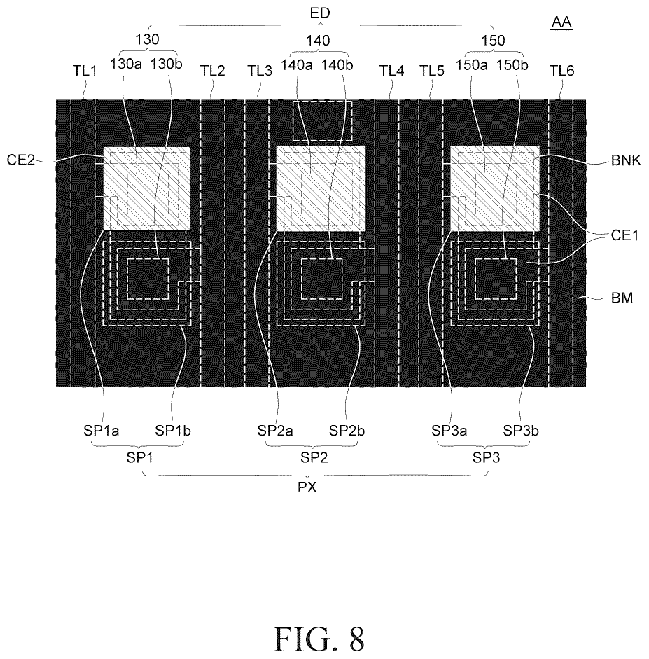

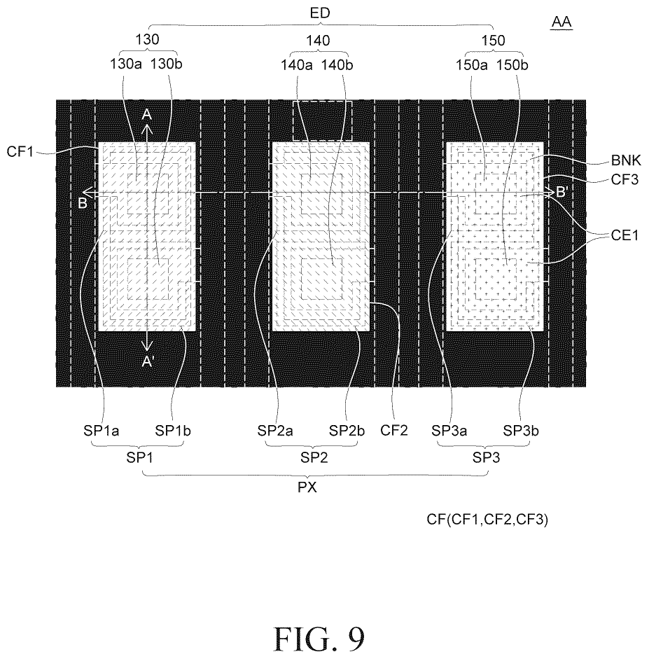

FIGS. 5 to 9 are top plan views of the display device according to an embodiment of the present disclosure. For example, FIGS. 5 and 7 are enlarged top plan views of the display area including the plurality of pixels. For example, FIGS. 6, 8, and 9 are enlarged top plan views of the display area including one pixel. FIGS. 5 and 6 illustrate a plurality of signal lines TL, a plurality of communication lines NL, a plurality of first electrodes CE1, a plurality of banks BNK, and a plurality of micro-LEDs ED according to an embodiment of the present disclosure. However, the embodiments of the present disclosure are not limited thereto. FIG. 7 is an enlarged top plan view illustrating a state in which a plurality of second electrodes CE2 are additionally disposed in FIG. 5 according to an embodiment of the present disclosure. FIG. 8 is an enlarged top plan view illustrating a state in which the second electrode CE2 and a black matrix BM are additionally disposed in FIG. 6 according to an embodiment of the present disclosure. FIG. 9 is an enlarged top plan view illustrating a state in which a color filter CF is additionally disposed in FIG. 8 according to an embodiment of the present disclosure.

With reference to FIGS. 5 and 6, the plurality of pixels PX including the plurality of subpixels may be disposed in the display area AA. The plurality of subpixels may each include the micro-LED ED and emit light independently. The plurality of subpixels may be disposed in a plurality of rows and a plurality of columns while defining a matrix shape. However, the embodiments of the present disclosure are not limited thereto.

The plurality of subpixels may include a first subpixel SP1, a second subpixel SP2, and a third subpixel SP3. For example, one of the first subpixel SP1, the second subpixel SP2, and the third subpixel SP3 may be a red subpixel, another subpixel may be a green subpixel, and the remaining subpixel may be a blue subpixel. The types of plurality of subpixels are illustrative. However, the embodiments of the present disclosure are not limited thereto.

The plurality of pixels PX may each include one or more first subpixels SP1, one or more second subpixels SP2, and one or more third subpixels SP3. For example, one pixel PX may include a pair of first subpixels SP1, a pair of second subpixels SP2, and a pair of third subpixels SP3. The pair of first subpixels SP1 may include a first-first subpixel SP1a and a first-second subpixel SP1b. The pair of second subpixels SP2 may include a second-first subpixel SP2a and a second-second subpixel SP2b. The pair of third subpixels SP3 may include a third-first subpixel SP3a and a third-second subpixel SP3b. For example, one pixel PX may include the first-first subpixel SP1a, the first-second subpixel SP1b, the second-first subpixel SP2a, the second-second subpixel SP2b, the third-first subpixel SP3a, and the third-second subpixel SP3b. However, the embodiments of the present disclosure are not limited thereto.

The plurality of subpixels constituting one pixel PX may be variously arranged. For example, in one pixel PX, the pair of first subpixels SP1 may be disposed in the same column, the pair of second subpixels SP2 may be disposed in the same column, and the pair of third subpixels SP3 may be disposed in the same column. The first subpixel SP1, the second subpixel SP2, and the third subpixel SP3 may be disposed in the same row. The number of and arrangement of the plurality of subpixels constituting one pixel PX are illustrative. However, the embodiments of the present disclosure are not limited thereto.

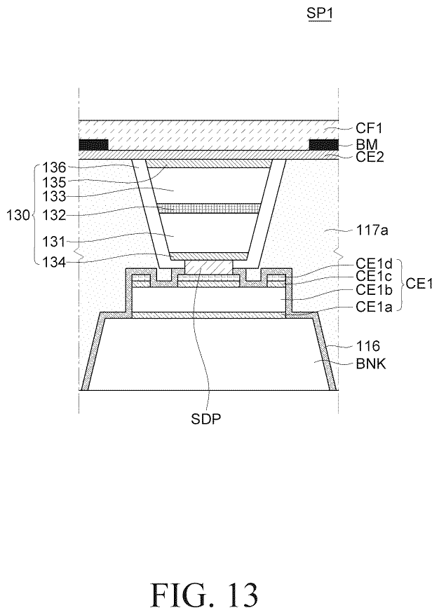

The plurality of signal lines TL may be disposed in areas between the plurality of subpixels. The plurality of signal lines TL may extend in the column direction between the plurality of subpixels. The plurality of signal lines TL may be lines configured to transmit an anode voltage from the pixel drive circuit PD to the plurality of subpixels. For example, the plurality of signal lines TL may be electrically connected to the plurality of pixel drive circuits PD and the first electrodes CE1 of the plurality of subpixels. The anode voltage outputted from the pixel drive circuit PD may be transmitted to the first electrodes CE1 of the plurality of subpixels through the plurality of signal lines TL. For example, the first electrode CE1 may be an electrode electrically connected to an anode electrode 134 (see FIG. 13) of the micro-LED ED. Therefore, the anode voltage from the signal line TL may be transmitted to the anode electrode 134 of the micro-LED ED through the first electrode CE1.

Therefore, the structure of the display device 1000 may be simplified by using the pixel drive circuit PD into which a plurality of pixel circuits are integrated instead of forming a plurality of transistors and a plurality of storage capacitors in the plurality of subpixels. In addition, because the circuits respectively disposed in the plurality of subpixels are integrated into one pixel drive circuit PD, the high-efficiency operation with low power consumption may be performed.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may each be electrically connected to each of the pair of first subpixels SP1. The third signal line TL3 and the fourth signal line TL4 may each be electrically connected to each of the pair of second subpixels SP2. The fifth signal line TL5 and the sixth signal line TL6 may each be electrically connected to each of the pair of third subpixels SP3.

The first signal line TL1 may be disposed at one side of the pair of first subpixels SP1, and the second signal line TL2 may be disposed at another side of the pair of first subpixels SP1. The first signal line TL1 may be electrically connected to one of the pair of first subpixels SP1, e.g., the first electrode CE1 of the first-first subpixel SP1a. The second signal line TL2 may be electrically connected to the remaining one of the pair of first subpixels SP1, e.g., the first electrode CE1 of the first-second subpixel SP1b.

The third signal line TL3 may be disposed at one side of the pair of second subpixels SP2, and the fourth signal line TL4 may be disposed at another side of the pair of second subpixels SP2. For example, the third signal line TL3 may be disposed adjacent to the second signal line TL2. The third signal line TL3 may be electrically connected to one of the pair of second subpixels SP2, e.g., the first electrode CE1 of the second-first subpixel SP2a. The fourth signal line TL4 may be electrically connected to the remaining one of the pair of second subpixels SP2, e.g., the first electrode CE1 of the second-second subpixel SP2b.

The fifth signal line TL5 may be disposed at one side of the pair of third subpixels SP3, and the sixth signal line TL6 may be disposed at another side of the pair of third subpixels SP3. For example, the fifth signal line TL5 may be disposed adjacent to the fourth signal line TL4. The sixth signal line TL6 may be disposed adjacent to the first signal line TL1 connected to the adjacent pixel PX. The fifth signal line TL5 may be electrically connected to one of the pair of third subpixels SP3, e.g., the first electrode CE1 of the third-first subpixel SP3a. The sixth signal line TL6 may be electrically connected to the remaining one of the pair of third subpixels SP3, e.g., the first electrode CE1 of the third-second subpixel SP3b.

The plurality of signal lines TL may be made of an electrically conductive material. For example, the plurality of signal lines TL may be made of an electrically conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO). However, the embodiments of the present disclosure are not limited thereto. In another example, the plurality of signal lines TL may have a multilayer structure made of an electrically conductive material. For example, the plurality of signal lines TL may have a multilayer structure made of titanium (Ti), aluminum (Al), titanium (Ti), and indium tin oxide (ITO). However, the embodiments of the present disclosure are not limited thereto.

The plurality of communication lines NL may be disposed in areas between the plurality of pixels PX. The plurality of communication lines NL may be disposed to extend in the row direction in the areas between the plurality of pixels PX. The plurality of communication lines NL may be disposed in the areas between the plurality of second electrodes CE2 and may not overlap the plurality of second electrodes CE2. For example, the plurality of communication lines NL may be lines used for short-range communication such as near field communication (NFC). The plurality of communication lines NL may serve as antennas. For example, the plurality of communication lines NL may be a plurality of connection lines and the like. However, the embodiments of the present disclosure are not limited thereto.

According to the embodiment of the present disclosure, the bank BNK may be disposed in each of the plurality of subpixels. The plurality of banks BNK may have structures on which the plurality of micro-LEDs ED are seated. The plurality of banks BNK may guide positions of the plurality of micro-LEDs ED during the process of transferring the plurality of micro-LEDs ED to the display device 1000. The plurality of micro-LEDs ED may be transferred onto the plurality of banks BNK during the process of transferring the plurality of micro-LEDs ED. The plurality of banks BNK may be bank patterns, structures, or the like. However, the embodiments of the present disclosure are not limited thereto.

The bank BNK of the first subpixel SP1, the bank BNK of the second subpixel SP2, and the bank BNK of the third subpixel SP3 may be disposed to be spaced apart from one another. The bank BNK of the first subpixel SP1, the bank BNK of the second subpixel SP2, and the bank BNK of the third subpixel SP3 may be configured to be separated from one another. Therefore, the banks BNK of the first subpixel SP1, the second subpixel SP2, and the third subpixel SP3, to which different types of micro-LEDs ED are transferred, may be easily identified.

The bank BNK of the first-first subpixel SP1a and the bank BNK of the first-second subpixel SP1b may be connected to each other, spaced apart from each other, or separated from each other. For example, the bank BNK of the first-first subpixel SP1a and the bank BNK of the first-second subpixel SP1b, on which the micro-LEDs ED of the same type are disposed, may be connected to each other, spaced apart from each other, or separated from each other in consideration of designs such as transfer process requirements. Further, the bank BNK of the second-first subpixel SP2a and the bank BNK of the second-second subpixel SP2b may be connected to each other, spaced apart from each other, or separated from each other. The bank BNK of the third-first subpixel SP3a and the bank BNK of the third-second subpixel SP3b may be connected to each other, spaced apart from each other, or separated from each other. Therefore, the banks BNK of the pair of first subpixels SP1, the banks BNK of the pair of second subpixels SP2, and the banks BNK of the pair of third subpixels SP3 may be variously formed. However, the embodiments of the present disclosure are not limited thereto.

For example, the plurality of banks BNK may be made of an organic insulating material. The plurality of banks BNK may each be configured as a single layer or multilayer made of an organic insulating material. For example, the plurality of banks BNK may be made of photoresist, polyimide (PI), an acrylic material, or the like. However, the embodiments of the present disclosure are not limited thereto.

The first electrode CE1 may be disposed in each of the plurality of subpixels. The first electrode CE1 may be disposed on the bank BNK. The first electrode CE1 may be electrically connected to one of the plurality of signal lines TL. At least a part of the first electrode CE1 may extend to the outside of the bank BNK and be electrically connected to the signal line TL closest to the first electrode CE1. For example, a part of the first electrode CE1 of the first-first subpixel SP1a may extend to one side area of the first-first subpixel SP1a and be electrically connected to the first signal line TL1, and a part of the first electrode CE1 of the first-second subpixel SP1b may extend to the other side area of the first-second subpixel SP1b and be electrically connected to the second signal line TL2. A part of the first electrode CE1 of the second-first subpixel SP2a may extend to one side area of the second-first subpixel SP2a and be electrically connected to the third signal line TL3, and a part of the first electrode CE1 of the second-second subpixel SP2b may extend to the other side area of the second-second subpixel SP2b and be electrically connected to the fourth signal line TL4. A part of the first electrode CE1 of the third-first subpixel SP3a may extend to one side area of the third-first subpixel SP3a and be electrically connected to the fifth signal line TL5, and a part of the first electrode CE1 of the third-second subpixel SP3b may extend to the other side area of the third-second subpixel SP3b and be electrically connected to the sixth signal line TL6.

The first electrode CE1 may be electrically connected to the anode electrode 134 of the micro-LED ED and transmit the anode voltage from the pixel drive circuit PD to the micro-LED ED through the signal line TL. Different voltages may be applied to the first electrode CE1 of each of the plurality of subpixels in accordance with the displayed images. For example, different voltages may be applied to the first electrode CE1 of each of the plurality of subpixels. Therefore, the first electrode CE1 may be a pixel electrode. However, the embodiments of the present disclosure are not limited thereto.

The first electrode CE1 may be made of an electrically conductive material. For example, the first electrode CE1 may be integrated with the plurality of signal lines TL. For example, the first electrode CE1 may be made of the same electrically conductive material as the plurality of signal lines TL. However, the embodiments of the present disclosure are not limited thereto. For example, the first electrode CE1 may be made of an electrically conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO). However, the embodiments of the present disclosure are not limited thereto. In another example, the first electrode CE1 may have a multilayer structure made of an electrically conductive material. For example, the plurality of first electrodes CE1 may each have a multilayer structure made of titanium (Ti), aluminum (Al), titanium (Ti), and indium tin oxide (ITO). However, the embodiments of the present disclosure are not limited thereto.

The micro-LED ED may be disposed in each of the plurality of subpixels. The plurality of micro-LEDs ED may be disposed on the bank BNK and the first electrode CE1. The plurality of micro-LEDs ED may be disposed on the first electrode CE1 and electrically connected to the first electrode CE1. Therefore, the micro-LED ED may emit light by receiving the anode voltage from the pixel drive circuit PD through the signal line TL and the first electrode CE1.

The plurality of micro-LEDs ED may include first micro-LEDs 130, second micro-LEDs 140, and third micro-LEDs 150. The first micro-LED 130 may be disposed in the first subpixel SP1. The second micro-LED 140 may be disposed in the second subpixel SP2. The third micro-LED 150 may be disposed in the third subpixel SP3. For example, the first micro-LED 130, the second micro-LED 140, and the third micro-LED 150 may be white micro-LEDs. That is, the plurality of micro-LEDs ED disposed in the first subpixel SP1, the second subpixel SP2, and the third subpixel SP3 may be micro-LEDs of the same type.

The first micro-LEDs 130 may include a first-first micro-LED 130a disposed in the first-first subpixel SP1a, and a first-second micro-LED 130b disposed in the first-second subpixel SP1b. The second micro-LEDs 140 may include a second-first micro-LED 140a disposed in the second-first subpixel SP2a, and a second-second micro-LED 140b disposed in the second-second subpixel SP2b. The third micro-LEDs 150 may include a third-first micro-LED 150a disposed in the third-first subpixel SP3a, and a third-second micro-LED 150b disposed in the third-second subpixel SP3b.

With reference to FIGS. 5, 6, and 7 together, the second electrode CE2 may be disposed in each of the plurality of subpixels. The second electrode CE2 may be disposed on the micro-LED ED. The second electrodes CE2 may be electrically connected to the pixel drive circuit PD through a plurality of contact electrodes CCE.

For example, the second electrode CE2 may be electrically connected to a cathode electrode 135 (see FIG. 13) of the micro-LED ED and transmit a cathode voltage from the pixel drive circuit PD to the micro-LED ED. The same cathode voltage may be applied to the second electrodes CE2 of the plurality of subpixels. For example, the same voltage may be applied to the second electrode CE2 and the cathode electrode 135 of the micro-LED ED in each of the plurality of subpixels. Therefore, the second electrode CE2 may be a common electrode. However, the embodiments of the present disclosure are not limited thereto.

At least some of the plurality of subpixels may share the second electrode CE2. At least some of the second electrodes CE2 of the plurality of subpixels may be electrically connected to one another. Because the same voltage is applied to the second electrodes CE2, at least some of the subpixels may use and share the second electrode CE2. For example, the second electrodes CE2 of the pixels PX of at least some of the plurality of pixels PX disposed in the same row may be connected to each other. For example, one second electrode CE2 may be disposed in each of the plurality of pixels PX. One second electrode CE2 may be disposed for each of n subpixels.

For example, some of the second electrodes CE2 of the plurality of subpixels may be disposed to be spaced apart or separated from one another. For example, the second electrodes CE2 connected to the pixels PX disposed in an n-th row and the second electrodes CE2 connected to the pixels PX disposed in an (n+1) row may be disposed to be spaced apart or separated from one another. For example, the plurality of second electrodes CE2 may be disposed to be spaced apart from one another with the plurality of communication lines NL interposed therebetween and extending in the row direction. Therefore, the number of subpixels may be larger than the number of second electrodes CE2. In another example, all the second electrodes CE2 in the plurality of subpixels may be connected to one another, and thus only one second electrode CE2 may be disposed on the substrate 110. However, the embodiments of the present disclosure are not limited thereto.

The plurality of second electrodes CE2 may be made of a transparent electrically conductive material. However, the embodiments of the present disclosure are not limited thereto. The plurality of second electrodes CE2 may be made of a transparent electrically conductive material, and the light emitted from the micro-LED ED may be directed toward an upper side of the second electrode CE2. For example, the second electrode CE2 may be made of a transparent electrically conductive material such as indium tin oxide (ITO), indium zinc oxide (IZO), or indium gallium zinc oxide (IGZO). However, the embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal lines TL. The plurality of second electrodes CE2 may each overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 and transmit the cathode voltage from the pixel drive circuit PD to the second electrode CE2.

For example, the display device 1000 may be manufactured by forming a plurality of micro-LEDs on a wafer and transferring the micro-LED to the substrate 110 of the display device 1000. Various types of defects may occur during the process of transferring the plurality of micro-LEDs ED having fine sizes to the substrate 110. For example, a non-transfer defect, which is caused when the micro-LEDs ED are not transferred, may occur in some of the subpixels, and a defect, in which the micro-LEDs ED are transferred while deviating from exact positions, may occur because of alignment errors in some of the subpixels. In addition, the transferred micro-LED ED may be defective even though the transfer process is normally performed. Therefore, the plurality of micro-LEDs ED of the same type may be transferred to one subpixel in consideration of defects occurring during the process of transferring the plurality of micro-LEDs ED. A lighting inspection may be performed on the plurality of micro-LEDs ED, and only one micro-LED ED, which is finally determined as being normal, may be used.

For example, both the first-first micro-LED 130a and the first-second micro-LED 130b are transferred to one subpixel, and whether the first-first micro-LED 130a and the first-second micro-LED 130b are defective may be inspected. If both the first-first micro-LED 130a and the first-second micro-LED 130b are determined as being normal, the first-first micro-LED 130a may be used, and the first-second micro-LED 130b may not be used. In another example, in case that the first-second micro-LED 130b between the first-first micro-LED 130a and the first-second micro-LED 130b is determined as being normal, the first-first micro-LED 130a may not be used, and the first-second micro-LED 130b may be used. Therefore, even though the plurality of micro-LEDs ED of the same type is transferred to one subpixel, only one micro-LED ED may be finally used.

Therefore, one of the pair of micro-LEDs ED may be a main (or primary) micro-LED ED, and the other of the micro-LEDs ED may be a redundancy micro-LED ED. The redundancy micro-LED ED may be an extra micro-LED ED transferred to prepare for a defect of the main micro-LED ED. When the main micro-LED ED is defective, the redundancy micro-LED ED may be used instead of the main micro-LED ED. Therefore, both the main micro-LED ED and the redundancy micro-LED ED are transferred to one subpixel, which may minimize a deterioration in display quality caused by defects of the main micro-LED ED and the redundancy micro-LED ED.

For example, the first-first micro-LED 130a, the second-first micro-LED 140a, and the third-first micro-LED 150a transferred to one pixel PX may be used as the main micro-LEDs ED, and the first-second micro-LED 130b, the second-second micro-LED 140b, and the third-second micro-LED 150b may be used as the redundancy micro-LEDs ED.

With reference to FIG. 8, the black matrix BM is disposed on the plurality of second electrodes CE2. The black matrix BM may minimize or at least reduce a color mixture of the light from the plurality of subpixels. The black matrix BM may be disposed on at least some of the plurality of micro-LEDs. The black matrix BM may be disposed on at least some of the plurality of micro-LEDs ED disposed in one subpixel. The black matrix BM may include opening portions through which at least some of the plurality of micro-LEDs are exposed. The black matrix BM may not be disposed on at least some of the plurality of micro-LEDs ED disposed in one subpixel.

The black matrix BM may be disposed in consideration of whether the plurality of micro-LEDs ED is defective. Before the black matrix BM is formed, whether the plurality of micro-LEDs ED is defective may be inspected, and the black matrix BM may be formed on the basis of the inspection result. The black matrix BM may be disposed on the defective micro-LED ED. The black matrix BM may not be disposed on the micro-LED ED that normally emits light. The micro-LED ED, which normally emits light, may be exposed by the black matrix BM. The black matrix BM in each of the plurality of subpixels may expose only one micro-LED ED that normally emits light. In case that all the plurality of micro-LEDs ED are normal in one subpixel, the black matrix BM may be disposed on another micro-LED ED, except for only one micro-LED ED selected arbitrarily.

With reference to FIG. 8, for example, in case that the first-first micro-LED 130a is normal and the first-second micro-LED 130b is defective in the first subpixel SP1, the black matrix BM may be disposed on the first-second micro-LED 130b but not the first-first micro-LED 130a. In case that the second-first micro-LED 140a is normal and the second-second micro-LED 140b is defective in the second subpixel SP2, the black matrix may be disposed on the second-second micro-LED 140b but not the second-first micro-LED 140a. In case that the third-first micro-LED 150a is normal and the third-second micro-LED 150b is defective in the third subpixel SP3, the black matrix BM may be disposed on the third-second micro-LED 150b but not the third-first micro-LED 150a. As described above, the plurality of micro-LEDs ED disposed in the same row in the plurality of subpixels may be exposed by the black matrix BM. However, the embodiments of the present disclosure are not limited thereto.

The black matrix BM may be made of an opaque material. For example, the black matrix BM may be made of an organic insulating material to which a black pigment is added.

With reference to FIG. 9, the color filter CF is disposed on the micro-LED ED exposed by the black matrix BM. The color filter CF may be disposed in a plurality of opening portions of the black matrix BM. The color filter CF may be disposed to completely cover the plurality of opening portions of the black matrix BM. The color filter CF implements light beams with various colors from the light beams emitted from the plurality of micro-LEDs ED. The color filters CF, which transmit light beams with different wavelengths, may be respectively disposed in the plurality of subpixels.

For example, a first color filter CF1 configured to transmit red light may be disposed in the first subpixel SP1. A second color filter CF2 configured to transmit green light may be disposed in the second subpixel SP2. A third color filter CF3 configured to transmit blue light may be disposed in the third subpixel SP3. The different color filters CF may be respectively disposed in the subpixels and implement light beams with various colors including white by combining red light, green light, and blue light.

In each of the plurality of subpixels, the color filter CF may extend onto the black matrix BM and overlap another adjacent micro-LED ED.

For example, in the first subpixel SP1, the first color filter CF1 may extend from the first-first micro-LED 130a onto the first-second micro-LED 130b. The first color filter CF1 may cover both the first-first micro-LED 130a and the first-second light-emitting element 130b. The black matrix BM and the first color filter CF1 may be stacked on the first-second micro-LED 130b. In the second subpixel SP2, the second color filter CF2 may extend from the second-first micro-LED 140a onto the second-second micro-LED 140b. The second color filter CF2 may cover both the second-first micro-LED 140a and the second-second micro-LED 140b. The black matrix BM and the second color filter CF2 may be stacked on the second-second micro-LED 140b. In the third subpixel SP3, the third color filter CF3 may extend from the third-first micro-LED 150a onto the third-second micro-LED 150b. The third color filter CF3 may cover both the third-first micro-LED 150a and the third-second micro-LED 150b. The black matrix BM and the third color filter CF3 may be stacked on the third-second micro-LED 150b.

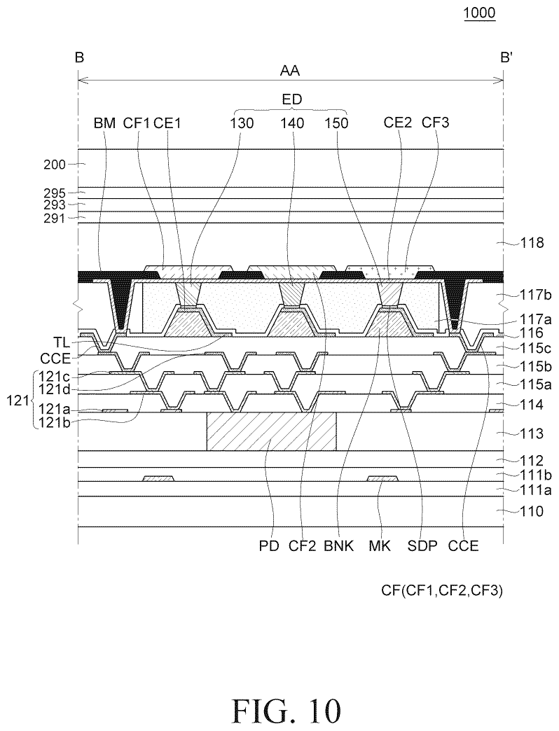

Hereinafter, a cross-sectional structure of the subpixel of the display device 1000 according to the embodiment of the present disclosure will be described with reference to FIGS. 10 to 13.

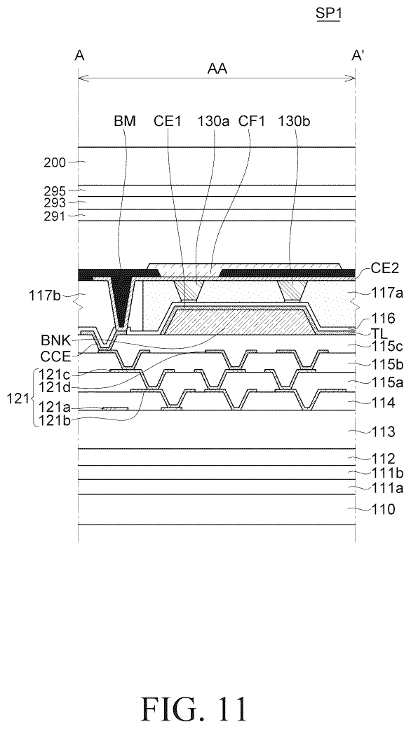

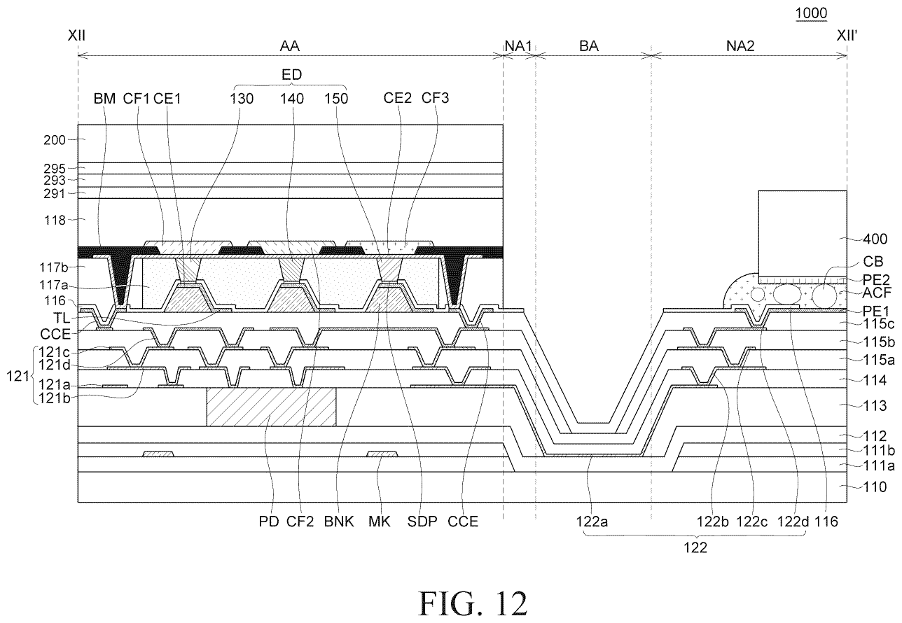

FIGS. 10 to 13 are cross-sectional views of the display device according to an embodiment of the present disclosure. For example, FIGS. 10 and 11 are cross-sectional views of the display area AA according to an embodiment of the present disclosure. For example, FIG. 12 is a cross-sectional view taken along line XII-XII′ in FIG. 3 according to an embodiment of the present disclosure. In another example, FIG. 12 is a cross-sectional view of the first non-display area NA, the bending area BA, and the second non-display area NA2. For example, FIG. 13 is an enlarged cross-sectional view of the first subpixel SP1 according to an embodiment of the present disclosure.

With reference to FIGS. 10 to 12, a first buffer layer 111a and a second buffer layer 111b may be disposed in the remaining area of the substrate 110, except for the bending area BA.

The first buffer layer 111a and the second buffer layer 111b may be disposed in the display area AA, the first non-display area NA1, and the second non-display area NA2. The first buffer layer 111a and the second buffer layer 111b may reduce the permeation of moisture or impurities through the substrate 110. The first buffer layer 111a and the second buffer layer 111b may be made of an inorganic insulating material. For example, the first buffer layer 111a and the second buffer layer 111b may each be configured as a single layer or multilayer made of silicon oxide (SiOx) or silicon nitride (SiNx). However, the embodiments of the present disclosure are not limited thereto.

For example, the first buffer layer 111a and the second buffer layer 111b disposed in the bending area BA may be partially removed. A top surface of the substrate 110 positioned in the bending area BA may be exposed from the first buffer layer 111a and the second buffer layer 111b. The first buffer layer 111a and the second buffer layer 111b, which are made of an inorganic insulating material, are removed from the bending area BA, which may minimize the occurrence of a crack in the first buffer layer 111a and the second buffer layer 111b that may be caused when the bending area BA is bent.

A plurality of alignment keys MK may be disposed between the first buffer layer 111a and the second buffer layer 111b. The plurality of alignment keys MK may be configured to identify a position of the pixel drive circuit PD during the process of manufacturing the display device 1000. For example, the plurality of alignment keys MK may be configured to align the position of the pixel drive circuit PD transferred onto a bonding layer 112. In another example, the plurality of alignment keys MK may be excluded.

The bonding layer 112 may be disposed on the second buffer layer 111b. The bonding layer 112 may be disposed in the display area AA, the first non-display area NA1, the bending area BA, and the second non-display area NA2. In another example, at least a part of the bonding layer 112 may be removed from the non-display area NA including the bending area BA. For example, the bonding layer 112 may be made of any one of polymer (adhesive polymer), epoxy resin, UV-curable resin, polyimide, acrylate, urethane, and polydimethylsiloxane (PDMS). However, the embodiments of the present disclosure are not limited thereto.

The pixel drive circuit PD may be disposed on the bonding layer 112 in the display area AA. In case that the pixel drive circuit PD is implemented as an operation driver, the operation driver may be mounted on the bonding layer 112 by the transfer process. However, the embodiments of the present disclosure are not limited thereto.

A first protective layer 113 may be disposed on the bonding layer 112 and the pixel drive circuit PD. The first protective layer 113 may be disposed to surround a side surface of the pixel drive circuit PD. However, the embodiments of the present disclosure are not limited thereto. For example, the first protective layer 113 may be disposed to cover at least a part of a top surface of the pixel drive circuit PD. For example, the first protective layer 113 may be excluded from the bending area BA. However, the embodiments of the present disclosure are not limited thereto. For example, the first protective layer 113 may be partially disposed in the display area AA, the first non-display area NA1, and the second non-display area NA2. For example, a part of the first protective layer 113 disposed in the bending area BA may be removed. However, the embodiments of the present disclosure are not limited thereto.

The first protective layer 113 may be provided as a plurality of layers. For example, in case that the first protective layer 113 is provided as a plurality of layers, at least one layer may be entirely disposed in the display area AA, the bending area BA, and the non-display areas NA1 and NA2. Further, another layer may be partially disposed in the display area AA, the first non-display area NA1, and the second non-display area NA2. However, the embodiments of the present disclosure are not limited thereto.

The first protective layer 113 may be made of an organic insulating material. However, the embodiments of the present disclosure are not limited thereto. For example, the first protective layer 113 may be made of photoresist, polyimide (PI), or a photo acrylic material. However, the embodiments of the present disclosure are not limited thereto. For example, the first protective layer 113 may be an overcoating layer or an insulation layer. However, the embodiments of the present disclosure are not limited thereto.

According to the embodiment of the present disclosure, a plurality of first connection lines 121 may be disposed on the first protective layer 113 in the display area AA. The plurality of first connection lines 121 may be lines configured to electrically connect the pixel drive circuit PD to other constituent elements. For example, the pixel drive circuit PD may be electrically connected to the plurality of signal lines TL, the plurality of contact electrodes CCE, and the like through the plurality of first connection lines 121. For example, the plurality of first connection lines 121 may include first-first connection lines 121a, first-second connection lines 121b, first-third connection lines 121c, and first-fourth connection lines 121d. However, the embodiments of the present disclosure are not limited thereto.

For example, the plurality of first-first connection lines 121a may be disposed on the first protective layer 113. The plurality of first-first connection lines 121a may be electrically connected to the pixel drive circuit PD. The plurality of first-first connection lines 121a may transmit a voltage, which is outputted from the pixel drive circuit PD, to the first electrode CE1 or the second electrode CE2.

For example, a second protective layer 114 may be disposed on the first protective layer 113. The second protective layer 114 may be entirely disposed in the display area AA and the non-display area NA. In the first non-display area NA1 and the second non-display area NA2, the second protective layer 114 may cover or surround a side surface and a top surface of the first protective layer 113. The second protective layer 114 may be made of an organic insulating material. For example, the second protective layer 114 may be made of photoresist, polyimide (PI), or a photo acrylic material. However, the embodiments of the present disclosure are not limited thereto. For example, the first protective layer 113 and the second protective layer 114 may be made of the same material. However, the embodiments of the present disclosure are not limited thereto.

The plurality of first-second connection lines 121b may be disposed on the second protective layer 114. The plurality of first-second connection lines 121b may be connected indirectly or directly to the pixel drive circuit PD. For example, a part of the first-second connection line 121b may be connected directly to the pixel drive circuit PD through a contact hole of the second protective layer 114. Another part of the first-second connection line 121b may be electrically connected to the first-first connection line 121a through the contact hole of the second protective layer 114. However, the embodiments of the present disclosure are not limited thereto. The voltage outputted from the pixel drive circuit PD may be transmitted to the first electrode CE1 or the second electrode CE2 through a connection line different from the plurality of first-second connection lines 121b.

A first insulation layer 115a may be disposed on the plurality of first-second connection lines 121b. The first insulation layer 115a may be entirely disposed in the display area AA and the non-display area NA. However, the embodiments of the present disclosure are not limited thereto. The first insulation layer 115a may be made of an organic insulating material. However, the embodiments of the present disclosure are not limited thereto. For example, the first insulation layer 115a may be made of photoresist, polyimide (PI), or a photo acrylic material. However, the embodiments of the present disclosure are not limited thereto.

The plurality of first-third connection lines 121c may be disposed on the first insulation layer 115a. The plurality of first-third connection lines 121c may be electrically connected to the plurality of first-second connection lines 121b. For example, the first-third connection line 121c may be electrically connected to the first-second connection line 121b through a contact hole of the first insulation layer 115a.

A second insulation layer 115b may be disposed on the plurality of first-third connection lines 121c. The second insulation layer 115b may be disposed in the remaining area, except for the bending area BA. However, the embodiments of the present disclosure are not limited thereto. The second insulation layer 115b may be disposed in the display area AA, the first non-display area NA1, and the second non-display area NA2. However, the embodiments of the present disclosure are not limited thereto. For example, a part of the second insulation layer 115b disposed in the bending area BA may be removed. The second insulation layer 115b may be made of an organic insulating material. However, the embodiments of the present disclosure are not limited thereto. For example, the second insulation layer 115b may be made of photoresist, polyimide (PI), or a photo acrylic material. However, the embodiments of the present disclosure are not limited thereto.

The plurality of first-fourth connection lines 121d may be disposed on the second insulation layer 115b. The plurality of first-fourth connection lines 121d may be electrically connected to the plurality of first-third connection lines 121c. For example, the first-fourth connection line 121d may be electrically connected to the first-third connection line 121c through the contact hole of the second insulation layer 115b.

According to the embodiment of the present disclosure, a plurality of second connection lines 122 may be disposed on the first protective layer 113 in the non-display area NA. The plurality of second connection lines 122 may be lines configured to transmit the signals, which are transmitted to the pad part PAD from the flexible circuit board (or flexible film) 400 and the printed circuit board 500 (see FIG. 1), to the pixel drive circuit PD in the display area AA. For example, the plurality of second connection lines 122 may be electrically connected to the plurality of pad electrodes PE and receive the signals from the flexible circuit board (or flexible film) 400 and the printed circuit board 500.

For example, the plurality of second connection lines 122 may extend from the pad part PAD toward the display area AA and transmit signals to the lines in the display area AA. In this case, the plurality of second connection lines 122 may serve as the link lines LL. The plurality of second connection lines 122 may include second-first connection lines 122a, second-second connection lines 122b, second-third connection lines 122c, and second-fourth connection lines 122d.

The plurality of second-first connection lines 122a may be disposed on the first protective layer 113. The plurality of second-first connection lines 122a may extend from the second non-display area NA2 to the bending area BA and the first non-display area NA1. The plurality of second-first connection lines 122a may transmit the signals, which are transmitted to the pad part PAD from the flexible circuit board (or flexible film) 400 and the printed circuit board 500, to the pixel drive circuit PD in the display area AA. For example, the plurality of second-first connection lines 122a may be disposed on the same layer as the plurality of first-first connection lines 121a. For example, the plurality of second-first connection lines 122a may be made of the same material as the plurality of first-first connection lines 121a.

The plurality of second-second connection lines 122b may be disposed on the second protective layer 114. The plurality of second-second connection lines 122b may be disposed in the second non-display area NA2. The second-second connection line 122b may be electrically connected to the second-first connection line 122a through the contact hole of the second protective layer 114. Therefore, the signals may be transmitted from the flexible circuit board (or flexible film) 400 and the printed circuit board 500 to the second-first connection line 122a through the second-second connection line 122b. For example, the plurality of second-second connection lines 122b may be disposed on the same layer as the plurality of first-second connection lines 121b. For example, the plurality of second-second connection lines 122b may be made of the same material as the plurality of first-second connection lines 121b.

The second-third connection line 122c may be disposed on the first insulation layer 115a. The second-third connection line 122c may be disposed in the second non-display area NA2. The second-third connection line 122c may be electrically connected to the second-second connection line 122b through the contact hole of the first insulation layer 115a. Therefore, the signals may be transmitted from the flexible circuit board (or flexible film) 400 and the printed circuit board to the second-first connection line 122a through the second-third connection line 122c and the second-second connection line 122b. For example, the plurality of second-third connection lines 122c may be disposed on the same layer as the plurality of first-third connection lines 121c. For example, the plurality of second-third connection lines 122c may be made of the same material as the plurality of first-third connection lines 121c.

The second-fourth connection line 122d may be disposed on the second insulation layer 115b. The second-fourth connection line 122d may be disposed in the second non-display area NA2. The second-fourth connection line 122d may be electrically connected to the second-third connection line 122c through the contact hole of the second insulation layer 115b. Therefore, the signals may be transmitted from the flexible circuit board (or flexible film) 400 and the printed circuit board 500 to the second-first connection line 122a through the second-fourth connection line 122d, the second-third connection line 122c, and the second-second connection line 122b. For example, the plurality of second-fourth connection lines 122d may be disposed on the same layer as the plurality of first-fourth connection lines 121d. For example, the plurality of second-fourth connection lines 122d may be made of the same material as the plurality of first-fourth connection lines 121d.

The plurality of first connection lines 121 and the plurality of second connection lines 122 may be made of any one of electrically conductive materials with excellent flexibility or various electrically conductive materials used for the display area AA. For example, the second connection line 122 partially disposed in the bending area BA may be made of an electrically conductive material, such as gold (Au), silver (Ag), or aluminum (Al), that is excellent in flexibility. However, the embodiments of the present disclosure are not limited thereto. In another example, the plurality of first connection lines 121 and the plurality of second connection lines 122 may be made of molybdenum (Mo), chromium (Cr), titanium (Ti), nickel (Ni), neodymium (Nd), copper (Cu), and an alloy of silver (Ag) and magnesium (Mg), or an alloy thereof. However, the embodiments of the present disclosure are not limited thereto.

A third insulation layer 115c may be disposed on the plurality of first connection lines 121 and the plurality of second connection lines 122. The third insulation layer 115c may be disposed in the remaining area, except for the bending area BA. However, the embodiments of the present disclosure are not limited thereto. The third insulation layer 115c may be disposed in the display area AA, the first non-display area NA1, and the second non-display area NA2. A part of the third insulation layer 115c disposed in the bending area BA may be removed. The third insulation layer 115c may be made of an organic insulating material. However, the embodiments of the present disclosure are not limited thereto. For example, the third insulation layer 115c may be made of photoresist, polyimide (PI), or a photo acrylic material. However, the embodiments of the present disclosure are not limited thereto.

The plurality of banks BNK may be disposed on the third insulation layer 115c in the display area AA. The plurality of banks BNK may be disposed to overlap the plurality of subpixels. Two or more micro-LEDs ED of the same type may be disposed on upper portions of the plurality of banks BNK. The plurality of signal lines TL may be electrically connected to the plurality of first-fourth connection lines 121d. For example, the plurality of signal lines TL may be electrically connected to the first-fourth connection line 121d through a contact hole of the third insulation layer 115c.

The plurality of signal lines TL may be disposed on the third insulation layer 115c in the display area AA. The plurality of signal lines TL may be disposed in areas between the plurality of banks BNK. For example, the plurality of signal lines TL may be disposed adjacent to any one of the plurality of banks BNK.

The plurality of contact electrodes CCE may be disposed on the third insulation layer 115c in the display area AA. The plurality of contact electrodes CCE may supply the cathode voltage from the pixel drive circuit PD to the second electrode CE2.

The first electrode CE1 may be disposed on the bank BNK. For example, the first electrode CE1 may be disposed to extend from the adjacent signal line TL to the upper side of the bank BNK. The first electrode CE1 may be disposed on the top surface of the bank BNK and the side surface of the bank BNK. For example, the first electrode CE1 may be disposed to extend from the signal line TL on the top surface of the third insulation layer 115c to the side surface of the bank BNK and the top surface of the bank BNK.

With reference to FIG. 13, the first electrode CE1 may include a plurality of conductive layers. For example, the first electrode CE1 may include a first conductive layer CE1a, a second conductive layer CE1b, a third conductive layer CE1c, and a fourth conductive layer CE1d. However, the embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may each be made of titanium (Ti), molybdenum (Mo), aluminum (Al), titanium (Ti), or indium tin oxide (ITO). However, the embodiments of the present disclosure are not limited thereto.

According to the embodiment of the present disclosure, among the plurality of conductive layers constituting the first electrode CE1, some conductive layers with high reflection efficiency may include alignment keys for aligning the micro-LEDs ED, and/or reflective plates. For example, among the plurality of conductive layers of the first electrode CE1, the second conductive layer CE1b may include a reflective material. For example, the second conductive layer CE1b may include aluminum (Al). However, the embodiments of the present disclosure are not limited thereto. Therefore, the second conductive layer CE1b may be configured as a reflective plate. In addition, with the high reflection efficiency of the second conductive layer CE1b, the second conductive layer CE1b may be easily identified during the manufacturing process. Therefore, the position or transfer position of the micro-LED ED may be aligned with respect to the second conductive layer CE1b.

For example, in order to configure the second conductive layer CE1b as a reflective plate, the third conductive layer CE1c and the fourth conductive layer CE1d, which cover the second conductive layer CE1b, may be partially removed or etched. For example, the third conductive layer CE1c and the fourth conductive layer CE1d disposed on the bank BNK may be partially removed or etched, such that a top surface of the second conductive layer CE1b may be exposed. For example, central portions where solder patterns SDP are disposed and rim portions (or edge portions) of the third conductive layer CE1c and the fourth conductive layer CE1d may be maintained, and the remaining portions excluding the above-mentioned portions may be removed. For example, the rim portion (or edge portion) of the third conductive layer CE1c made of titanium (Ti) and the rim portion (or edge portion) of the fourth conductive layer CE1d made of indium tin oxide (ITO) may not be etched. Therefore, it is possible to inhibit the other conductive layers of the first electrode CE1 from being corroded by a tetramethyl ammonium hydroxide (TMAH) solution used for a mask process for the first electrode CE1.

According to the embodiment of the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer made of indium tin oxide (ITO) or indium zinc oxide (IZO) having high bondability to the solder pattern SDP and having corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process. However, the embodiments of the present disclosure are not limited thereto.

According to the embodiment of the present disclosure, the signal line TL, the contact electrode CCE, and the pad electrode PE disposed on the same layer as the first electrode CE1 may each be configured as a multilayer made of an electrically conductive material. However, the embodiments of the present disclosure are not limited thereto. For example, the signal line TL, the contact electrode CCE, and the pad electrode PE may each be configured as a multilayer made of indium tin oxide (ITO), titanium (Ti), aluminum (Al), and titanium (Ti). However, the embodiments of the present disclosure are not limited thereto.

According to the embodiment of the present disclosure, the solder pattern SDP may be disposed on the first electrode CE1 in each of the plurality of subpixels. The solder pattern SDP may electrically connect the first electrode CE1 and the micro-LED ED by bonding the micro-LED ED to the first electrode CE1. For example, the first electrode CE1 and the anode electrode 134 of the micro-LED ED may be electrically connected by eutectic bonding using the solder pattern SDP. However, the embodiments of the present disclosure are not limited thereto. For example, in case that the solder pattern SDP is made of indium (In) and the anode electrode 134 of the micro-LED ED is made of gold (Au), the solder pattern SDP and the anode electrode 134 may be joined by applying heat and pressure during the process of transferring the micro-LED ED. The micro-LED ED may be joined to the solder pattern SDP and the first electrode CE1 by eutectic bonding without a separate bonding material. For example, the solder pattern SDP may be made of indium (In), tin (Sn), or an alloy thereof. However, the embodiments of the present disclosure are not limited thereto. For example, the solder pattern SDP may be a bonding pad or a joining pad. However, the embodiments of the present disclosure are not limited thereto.

According to the embodiment of the present disclosure, a passivation layer 116 may be disposed on the plurality of signal lines TL, the plurality of first electrodes CE1, the plurality of contact electrodes CCE, and the third insulation layer 115c. For example, the passivation layer 116 may be disposed in the display area AA, the first non-display area NA1, and the second non-display area NA2. A part of the passivation layer 116 disposed in the bending area BA may be removed. A part of the passivation layer 116, which covers the plurality of pad electrodes PE in the second non-display area NA2, may be removed. The passivation layer 116 is disposed to cover the remaining area excluding the areas in which the bending area BA, the plurality of pad electrodes PE, and the solder pattern SDP are disposed, and as a result, it is possible to reduce the permeation of moisture or impurities introduced into the micro-LED ED. For example, the passivation layer 116 may be configured as a single layer or multilayer made of silicon oxide (SiOx) or silicon nitride (SiNx). However, the embodiments of the present disclosure are not limited thereto. For example, the passivation layer 116 may be a protective layer, an insulation layer, or the like. However, the embodiments of the present disclosure are not limited thereto. For example, the passivation layer 116 may include a hole through which the solder pattern SDP is exposed.

In each of the plurality of subpixels, the micro-LED ED may be disposed on the solder pattern SDP. The first micro-LED 130 may be disposed in the first subpixel SP1. The second micro-LED 140 may be disposed in the second subpixel SP2. The third micro-LED 150 may be disposed in the third subpixel SP3.

The micro-LED ED may be formed on a silicon wafer by a method such as metal-organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering. However, the embodiments of the present disclosure are not limited thereto.

With reference to FIG. 13, the first micro-LED 130 may include the anode electrode 134, a first semiconductor layer 131, an active layer 132, a second semiconductor layer 133, the cathode electrode 135, and an encapsulation film 136. However, the embodiments of the present disclosure are not limited thereto. For example, the first micro-LED 130 may not include the encapsulation film 136.

The first semiconductor layer 131 may be disposed on the solder pattern SDP. The second semiconductor layer 133 may be disposed on the first semiconductor layer 131. As shown in FIG. 13, the first semiconductor layer 131 may be disposed above the solder pattern SDP with the anode electrode 134 in between, and second semiconductor layer 133 may be disposed above the first semiconductor layer 131 with the active layer 132 in between.

For example, one of the first semiconductor layer 131 and the second semiconductor layer 133 may be implemented as a III-V group or II-VI group compound semiconductor and doped with impurities (or dopant). For example, one of the first semiconductor layer 131 and the second semiconductor layer 133 may be a semiconductor layer doped with n-type impurities, and the other of the first semiconductor layer 131 and the second semiconductor layer 133 may be a semiconductor layer doped with p-type impurities. However, the embodiments of the present disclosure are not limited thereto. For example, one of or both the first semiconductor layer 131 and the second semiconductor layer 133 may be layers made by doping a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs) with n-type or p-type impurities. However, the embodiments of the present disclosure are not limited thereto. For example, the n-type impurity may be silicon (Si), germanium (Ge), selenium (Se), carbon (C), tellurium (Te), tin (Sn), or the like. However, the embodiments of the present disclosure are not limited thereto. For example, the p-type impurity may be magnesium (Mg), zinc (Zn), calcium (Ca), strontium (Sr), barium BA, beryllium (Be), or the like. However, the embodiments of the present disclosure are not limited thereto.

For example, the first semiconductor layer 131 and the second semiconductor layer 133 may be respectively a nitride semiconductor containing n-type impurities and a nitride semiconductor containing p-type impurities. However, the embodiments of the present disclosure are not limited thereto. For example, the first semiconductor layer 131 may be a nitride semiconductor containing p-type impurities, and the second semiconductor layer 133 may be a nitride semiconductor containing n-type impurities. However, the embodiments of the present disclosure are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may have any one of a single well structure, a multi-well structure, a single quantum well structure, a multi-quantum well (MQW) structure, a quantum dot structure, and a quantum line structure. However, the embodiments of the present disclosure are not limited thereto. For example, the active layer 132 may be made of indium gallium nitride (InGaN), gallium nitride (GaN), or the like. However, the embodiments of the present disclosure are not limited thereto.

In another example, the active layer 132 may include a multi-quantum well (MQW) structure having a well layer, and a barrier layer having a higher band gap than the well layer. For example, the active layer 132 may configure an InGaN layer as the well layer and configure an AlGaN layer as the barrier layer. However, the embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage outputted from the pixel drive circuit PD may be applied to the first semiconductor layer 131 through the signal line TL, the first electrode CE1, and the anode electrode 134. For example, the anode electrode 134 may be made of an electrically conductive material that may be bonded to the solder pattern SDP by eutectic bonding. However, the embodiments of the present disclosure are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, the embodiments of the present disclosure are not limited thereto.

The cathode electrode 135 may be disposed on the second semiconductor layer 133. For example, the cathode electrode 135 may electrically connect the second semiconductor layer 133 and the second electrode CE2. The cathode voltage outputted from the pixel drive circuit PD may be applied to the second semiconductor layer 133 through the contact electrode CCE, the second electrode CE2, and the cathode electrode 135. The cathode electrode 135 may be made of a transparent electrically conductive material so that the light emitted from the micro-LED ED may propagate to the upper side of the micro-LED ED. However, the embodiments of the present disclosure are not limited thereto. For example, the cathode electrode 135 may be made of a material such as indium tin oxide (ITO), indium zinc oxide (IZO), or indium gallium zinc oxide (IGZO). However, the embodiments of the present disclosure are not limited thereto.

The encapsulation film 136 may be at least partially disposed on the first semiconductor layer 131, the active layer 132, the second semiconductor layer 133, the anode electrode 134, and the cathode electrode 135. For example, the encapsulation film 136 may at least partially surround the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and at least a part of the cathode electrode 135, e.g., an rim portion (or edge portion or one side) of the anode electrode 134 and an rim portion (or edge portion or one side) of the cathode electrode 135. At least a part of the anode electrode 134 may be exposed from the encapsulation film 136, such that the anode electrode 134 and the solder pattern SDP may be connected. For example, at least a part of the cathode electrode 135 may be exposed from the encapsulation film 136, such that the cathode electrode 135 and the second electrode CE2 may be connected. For example, the encapsulation film 136 may be made of an insulating material such as silicon nitride (SiNx) or silicon oxide (SiOx). However, the embodiments of the present disclosure are not limited thereto.

In another example, the encapsulation film 136 may have a structure in which a reflective material is dispersed in a resin layer. However, the embodiments of the present disclosure are not limited thereto. For example, the encapsulation film 136 may be manufactured as a reflector having various structures. However, the embodiments of the present disclosure are not limited thereto. The light emitted from the active layer 132 is reflected upward by the encapsulation film 136, which may improve the light extraction efficiency. For example, the encapsulation film 136 may be a reflective layer. However, the embodiments of the present disclosure are not limited thereto.

According to the present disclosure, the micro-LED ED may have a vertical structure. However, the embodiments of the present disclosure are not limited thereto. For example, the micro-LED ED may have a lateral structure or a flip chip structure.

The first micro-LED 130 has been described with reference to FIG. 13. The second micro-LED 140 and the third micro-LED 150 may have substantially the same structure as the first micro-LED 130. For example, the first semiconductor layer 131, the active layer 132, the second semiconductor layer 133, the anode electrode 134, the cathode electrode 135, and the encapsulation film 136 of the first micro-LED 130 may be substantially identical to those of the second micro-LED 140 and the third micro-LED 150.

According to the embodiment of the present disclosure, first optical layers 117a may be disposed to surround the plurality of micro-LEDs ED in the display area AA. For example, the first optical layers 117a may be disposed to surround the plurality of micro-LEDs ED and the bank BNK in the areas of the plurality of subpixels. The first optical layers 117a may be disposed between the plurality of micro-LEDs ED included in one pixel PX and between the plurality of banks BNK or cover the plurality of micro-LEDs ED and the plurality of banks BNK. For example, the first optical layers 117a may extend in a first (row) direction and be disposed to be spaced apart from each other in a second (column) direction. The first optical layer 117a may be disposed below the second electrode CE2. For example, the first optical layer 117a may be disposed between the passivation layer 116 and the second electrode CE2 and surround a lateral portion of the micro-LED ED and a lateral portion of the bank BNK. The first optical layer 117a may not be disposed on the plurality of micro-LEDs ED. For example, the first optical layer 117a may be a diffusion layer, a sidewall diffusion layer, or the like. However, the embodiments of the present disclosure are not limited thereto.

The first optical layer 117a may include an organic insulating material in which fine particles are dispersed. However, the embodiments of the present disclosure are not limited thereto. For example, the first optical layer 117a may be made of siloxane in which fine metal particles such as titanium dioxide (TiO₂) particles are dispersed. However, the embodiments of the present disclosure are not limited thereto. The light emitted from the plurality of micro-LEDs ED may be scattered by the fine particles dispersed in the first optical layer 117a and the light may be discharged to the outside of the display device 1000. Therefore, the first optical layer 117a may improve the efficiency in extracting light emitted from the plurality of micro-LEDs ED.

For example, the first optical layer 117a may be respectively disposed in the plurality of pixels PX or disposed together with some of the pixels PX disposed in the same row. However, the embodiments of the present disclosure are not limited thereto. For example, the first optical layer 117a may be disposed in each of the plurality of pixels PX or the plurality of pixels PX may share one first optical layer 117a. In another example, the plurality of subpixels may each separately include the first optical layer 117a. However, the embodiments of the present disclosure are not limited thereto.

According to the embodiment of the present disclosure, a second optical layer 117b may be disposed on the passivation layer 116 in the display area AA. For example, the second optical layer 117b may be disposed to surround the first optical layer 117a. For example, the second optical layer 117b may adjoin a side surface of the first optical layer 117a. For example, the second optical layer 117b may be disposed in an area between the plurality of pixels PX. However, the embodiments of the present disclosure are not limited thereto. For example, the second optical layer 117b may be a diffusion layer, a diffusion layer window, a window diffusion layer, or the like. However, the embodiments of the present disclosure are not limited thereto.

The second optical layer 117b may be made of an organic insulating material. However, the embodiments of the present disclosure are not limited thereto. The second optical layer 117b may be made of the same material as the first optical layer 117a. However, the embodiments of the present disclosure are not limited thereto. For example, the first optical layer 117a may include fine particles and the second optical layer 117b may lack fine particles. For example, the second optical layer 117b may be made of siloxane. However, the embodiments of the present disclosure are not limited thereto.

For example, a top surface of the first optical layer 117a and a top surface of the second optical layer 117b may be positioned on the same plane. However, the embodiments of the present disclosure are not limited thereto. Therefore, when viewed in a plan view, the top surface of the first optical layer 117a and the top surface of the second optical layer 117b may have flat shapes.

According to the embodiment of the present disclosure, the second electrode CE2 may be disposed on the first optical layer 117a and the second optical layer 117b. For example, the second electrode CE2 may be electrically connected to the plurality of contact electrodes CCE through the contact hole of the second optical layer 117b. For example, the second electrode CE2 may be disposed on the plurality of micro-LEDs ED. For example, the second electrode CE2 may include a transparent conductive oxide made of indium tin oxide (ITO), indium zinc oxide (IZO), or the like. However, the embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover an outer flat surface of the first optical layer 117a.

The second electrode CE2 may continuously extend in a first direction of the substrate 110. Therefore, the second electrode CE2 may be connected in common to the plurality of pixels PX arranged in the first direction of the substrate 110. For example, the second electrode CE2 may be connected in common to the plurality of pixels PX.

According to the present disclosure, the second electrode CE2 may continuously extend on the first optical layer 117a, the second optical layer 117b, and the micro-LED ED. Because the top surfaces of the first optical layer 117a and the second optical layer 117b are flat, the second electrode CE2, which is disposed on the first optical layer 117a and the second optical layer 117b, may also be disposed flat. The second electrode CE may be disposed flat without a level difference at a boundary between the first optical layer 117a and the second optical layer 117b.

In the display area AA, the black matrix BM may be disposed on the second electrode CE2, the first optical layer 117a, and the second optical layer 117b. For example, the contact hole of the second optical layer 117b may be filled with the black matrix BM. Because the black matrix BM is configured to cover the display area AA, it is possible to reduce a color mixture of the light emitted from the plurality of subpixels and external light reflection. For example, the black matrix BM is disposed even in the contact hole through which the second electrode CE2 and the contact electrode CCE are connected, which may suppress a leak of light between the plurality of adjacent subpixels.

According to the embodiment of the present disclosure, the black matrix BM is disposed on one micro-LED ED among the plurality of micro-LEDs ED respectively disposed in the plurality of subpixels. Therefore, the black matrix BM may expose another micro-LED ED among the plurality of micro-LEDs ED. The black matrix BM may include the plurality of opening portions for exposing the micro-LEDs ED.

For example, in the first subpixel SP1, the black matrix may be disposed on the first-second micro-LED 130b without being disposed on the first-first micro-LED 130a. Therefore, in the first subpixel SP1, the black matrix may expose the first-first micro-LED 130a. FIG. 11 illustrates a cross-sectional structure of the first subpixel SP1, but the second subpixel SP2 and the third subpixel SP3 may also have substantially the same structure.

The black matrix BM may be made of an opaque material. However, the embodiments of the present disclosure are not limited thereto. For example, the black matrix BM may be made of an organic insulating material to which a black pigment or a black dye is added. However, the embodiments of the present disclosure are not limited thereto.

The color filter CF may be disposed on the micro-LED ED exposed by the black matrix BM in each of the subpixels. The micro-LED ED exposed by the black matrix BM may be completely covered by the color filter CF. The color filter CF may be disposed in the plurality of opening portions of the black matrix BM. The color filter CF may be disposed in the opening portion of the black matrix BM and thus adjoin the second electrode CE2.

Different types of color filters CF may be disposed in the subpixels. For example, the first color filter CF1 configured to transmit a wavelength of a first color may be disposed in the first subpixel SP1. The second color filter CF2 configured to transmit a wavelength of a second color may be disposed in the second subpixel SP2. The third color filter configured to transmit a wavelength of a third color may be disposed in the third subpixel SP3. For example, the first color, the second color, and the third color may be respectively red, green, and blue colors. However, the embodiments of the present disclosure are not limited thereto.

According to the embodiment of the present disclosure, the color filter CF may extend onto the black matrix BM from the micro-LED ED exposed by the black matrix BM. The color filter CF may be disposed to extend to the top surface of the black matrix BM adjacent to the opening portion. Therefore, the color filter CF may overlap another adjacent micro-LED ED. For example, in the first subpixel SP1, the first color filter CF1 may extend from the opening portion of the black matrix BM for exposing the first-first micro-LED 130a to the first-second micro-LED 130b adjacent to the first-first micro-LED 130a and covered by the black matrix BM, thereby overlapping the first-second micro-LED 130b. The top surface of the color filter CF may be higher than the top surface of the black matrix BM. In the present disclosure, the bottom surface may refer to a surface adjacent to the substrate 110, and the top surface may refer to a rear surface opposite to the bottom surface. For example, the bottom surface of the color filter CF may refer to a surface closest to the substrate 110. In addition, the top surface of the color filter CF may refer to a rear surface opposite to the bottom surface.

In one subpixel, the color filter CF disposed in the opening portion of the black matrix BM and the color filter CF disposed on the black matrix BM may have different thicknesses. For example, the thickness of the color filter CF disposed in the opening portion of the black matrix BM may be larger than the thickness of the color filter CF disposed on the black matrix BM.

A cover layer 118 may be disposed on the color filter CF and the black matrix BM in the display area AA. The cover layer 118 may protect components disposed below the cover layer 118. For example, the cover layer 118 may be made of an organic insulating material. However, the embodiments of the present disclosure are not limited thereto. For example, the cover layer 118 may be made of photoresist, polyimide (PI), or a photo acrylic material. However, the embodiments of the present disclosure are not limited thereto. For example, the cover layer 118 may be an overcoating layer, an insulation layer, or the like. However, the embodiments of the present disclosure are not limited thereto.

The polarizing layer 293 may be disposed on the cover layer 118 by means of a first bonding layer 291. The cover member 200 may be disposed on the polarizing layer 293 by means of a second bonding layer 295. For example, the first bonding layer 291 and the second bonding layer 295 may each include an optically clear adhesive (OCA), an optically clear resin (OCR), a pressure-sensitive adhesive (PSA), or the like. However, the embodiments of the present disclosure are not limited thereto.

According to the embodiment of the present disclosure, the plurality of pad electrodes PE may be disposed on the third insulation layer 115c in the second non-display area NA2. For example, the plurality of pad electrodes PE may be at least partially exposed from the passivation layer 116. For example, the plurality of pad electrodes PE may be electrically connected to the second-fourth connection line 122d through the contact hole of the third insulation layer 115c.

A bonding layer ACF may be disposed on the plurality of pad electrodes PE. The bonding layer ACF may be a bonding layer made by dispersing conductive balls in an insulating material. However, the embodiments of the present disclosure are not limited thereto. In case that heat or pressure is applied to the bonding layer ACF, the conductive balls are electrically connected in a portion to which heat or pressure is applied, such that the bonding layer ACF may have conductive properties. The bonding layer ACF may be disposed between the plurality of pad electrodes PE and the flexible circuit board (or flexible film) 400 and attach or bond the flexible circuit board (or flexible film) 400 to the plurality of pad electrodes PE. For example, the bonding layer ACF may be an anisotropic conductive film (ACF). However, the embodiments of the present disclosure are not limited thereto.

The flexible circuit board (or flexible film) 400 may be disposed on the bonding layer ACF. The flexible circuit board (or flexible film) 400 may be electrically connected to the plurality of pad electrodes PE through the bonding layer ACF. Therefore, the signals outputted from the flexible circuit board (or flexible film) 400 and the printed circuit board 500 may be transmitted to the pixel drive circuit PD in the display area AA through the plurality of pad electrodes PE, the second-fourth connection line 122d, the second-third connection line 122c, the second-second connection line 122b, and the second-first connection line 122a.

The display device may be manufactured by transferring the micro-LEDs that emit light beams with different colors for the respective subpixels. However, during the above-mentioned manufacturing process, the transfer processes may be separately performed in accordance with the types of micro-LEDs to be disposed. For example, at least three processes need to be performed to transfer the micro-LEDs because the red micro-LED needs to be transferred to the red subpixel, the green micro-LED needs to be transferred to the green subpixel, and the blue micro-LED needs to be transferred to the blue subpixel.

However, according to the display device 1000 according to the embodiment of the present disclosure, the micro-LEDs ED of the same type are disposed in all the plurality of subpixels, such that the micro-LEDs ED may be transferred by the single process. That is, the plurality of processes of transferring different types of micro-LEDs ED may be reduced to the single process. As described above, the display device 1000 according to the embodiment of the present disclosure may reduce the production energy by optimizing the process.

Meanwhile, when the plurality of micro-LEDs are transferred onto the substrate of the display panel, there may occur an area in which an interval between the plurality of micro-LEDs is not uniform because of a process deviation or the like. In case that the interval between the plurality of micro-LEDs is not uniform, light-emitting areas of the plurality of micro-LEDs may be disposed non-uniformly, and a user may visually recognize a Mura. As described above, as a method for suppressing the visual recognition of the Mura, a separate optical layer may be further disposed on the plurality of micro-LEDs. However, when the separate optical layer is disposed on the micro-LED as described above, the manufacturing process may be complicated, and the process efficiency may deteriorate.

However, according to the display device 1000 according to the embodiment of the present disclosure, the color filter CF is disposed on the micro-LED ED visually recognized by the user among the plurality of micro-LEDs ED. Therefore, the light-emitting area visually recognized by the user may be determined by the color filter CF instead of the plurality of micro-LEDs ED. Therefore, the light-emitting area may be uniformly adjusted even though the interval between the plurality of micro-LEDs ED is not uniform because of the misalignment of the transfer positions of the plurality of micro-LEDs ED during the transfer process. Therefore, it is possible to reduce a situation in which the light emitted from some of the micro-LEDs is visually recognized as a Mura, and as a result, it is possible to improve the luminance uniformity of the display device 1000.

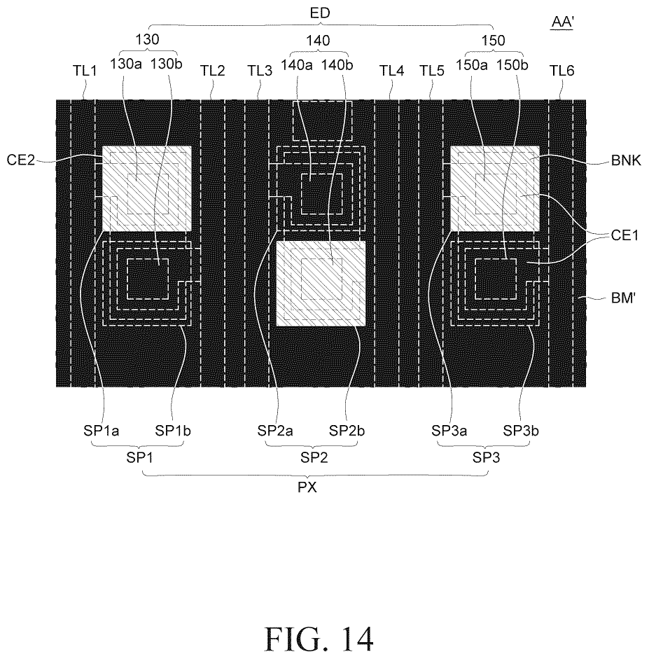

FIG. 14 is a top plan view of a display device according to another embodiment of the present disclosure. For example, FIG. 14 is an enlarged top plan view of a display area AA′ of the display device according to another embodiment of the present disclosure. The display device in FIG. 14 is substantially identical in configurations to that in the embodiment in FIGS. 1 to 13, except for the disposition of opening portions of a black matrix BM′.

With reference to FIG. 14, for example, in case that the first-first micro-LED 130a is normal and the first-second micro-LED 130b is defective in the first subpixel SP1, the black matrix BM′ may be disposed only on the first-second micro-LED 130b. In case that the second-first micro-LED 140a is defective and the second-second micro-LED 140b is normal in the second subpixel SP2, the black matrix BM′ may be disposed on the second-first micro-LED 140a but not the second-second micro-LED 140b. In case that the third-first micro-LED 150a is normal and the third-second micro-LED 150b is defective in the third subpixel SP3, the black matrix BM′ may be disposed on the third-second micro-LED 150b but not the third-first micro-LED 150a. As described above, according to the display device according to another embodiment of the present disclosure, the micro-LEDs ED disposed in different rows may be alternately exposed by the black matrix BM′ in the plurality of subpixels. However, the micro-LED ED exposed by the black matrix BM′ may be selected in consideration of whether the micro-LED ED is defective. Therefore, the opening portions of the black matrix BM′ may be randomly arranged on the plurality of micro-LEDs ED without any particular tendency.

Meanwhile, all the plurality of micro-LEDs ED respectively disposed in the plurality of subpixels may be normal.

According to the display device according to another embodiment of the present disclosure, the micro-LEDs ED of the same type are disposed in all the plurality of subpixels, which may minimize the number of processes of transferring the micro-LEDs ED. As described above, the display device according to the embodiment of the present disclosure may reduce the production energy by optimizing the process.

In addition, according to the display device according to another embodiment of the present disclosure, the light-emitting area may be uniformly adjusted even if a deviation between the transfer positions of the micro-LEDs ED occurs because of the misalignment of the transfer positions of the plurality of micro-LEDs ED during the transfer process. Therefore, it is possible to reduce a situation in which the light emitted from some of the micro-LEDs is visually recognized as a Mura, and as a result, it is possible to improve the luminance uniformity of the display device.

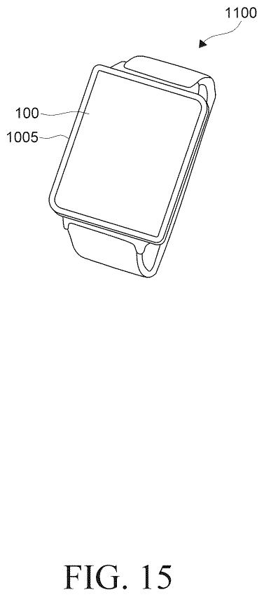

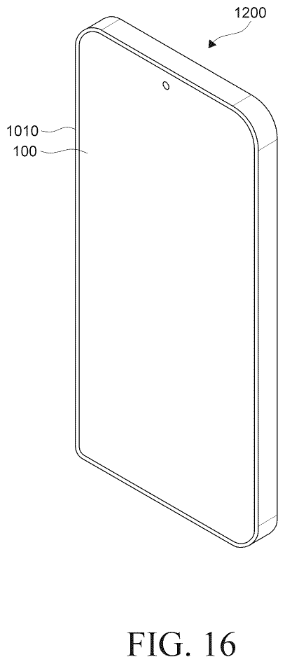

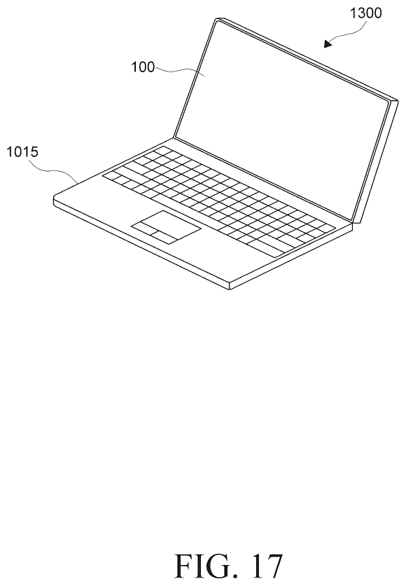

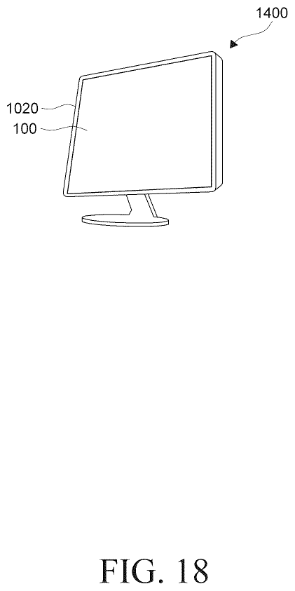

FIGS. 15 to 18 are views illustrating devices to which the display device according to the embodiments of the present disclosure are applied.

With reference to FIGS. 15 to 18, the display device 1000 according to the embodiments of the present disclosure may be included in various devices or electronic devices. For example, with reference to FIGS. 15 to 18, various electronic devices may include a wearable device 1100, a mobile device 1200, a notebook computer 1300, and a monitor or TV 1400. However, the embodiments of the present disclosure are not limited thereto.

The wearable device 1100, the mobile device 1200, the notebook computer 1300, and the monitor or TV 1400 may each respectively include a casing part 1005, 1010, 1015, or 1020, and the display panel 100 or the display device 1000 according to the embodiments of the present disclosure described with reference to FIGS. 1 to 14.

For example, the display device according to the embodiment of the present disclosure may be applied to a mobile device, an image telephone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical instrument, a desktop PC, a laptop PC, a netbook computer, a workstation, a navigation system, a display device for a vehicle, a display device for a theater, a television, a wallpaper device, a signage device, a gaming device, a notebook, a monitor, a camera, a camcorder, a household electrical appliance, and the like.

The exemplary embodiments of the present disclosure can also be described as follows:

A display device according to as aspect of the present disclosure comprises a substrate, a pixel drive circuit disposed on the substrate, a bank disposed on the pixel drive circuit, a plurality of micro-LEDs disposed on the bank and electrically connected to the pixel drive circuit, a color filter disposed on one of the plurality of micro-LEDs, and a black matrix disposed on another of the plurality of micro-LEDs.

The plurality of micro-LEDs may be white micro-LEDs.

The black matrix may comprise an opening portion through which one micro-LED is exposed.

The color filter may be disposed in the opening portion.

The color filter may extend to the black matrix and may be disposed to overlap another micro-LED.

A top surface of the color filter may be higher than a top surface of the black matrix.

The display device may further comprise a plurality of first electrodes disposed on the bank and connected to the plurality of micro-LEDs, and a second electrode disposed between the plurality of micro-LEDs, the black matrix, and the color filter and connected to the plurality of micro-LEDs.

The second electrode may be disposed flat.

The display device may further comprise an optical layer configured to surround side surfaces of the plurality of micro-LEDs and may be disposed below the second electrode.

Each of the plurality of micro-LEDs may comprise an anode electrode, a first semiconductor layer disposed on the anode electrode, an active layer disposed on the first semiconductor layer, a second semiconductor layer disposed on the active layer, and a cathode electrode disposed on the second semiconductor layer.

The display device may further comprise a first electrode disposed below the plurality of micro-LEDs and may be configured to electrically connect the pixel drive circuit and the anode electrode of each of the plurality of micro-LEDs, and a solder pattern disposed between the first electrode and the anode electrode, wherein the first electrode and the anode electrode may be electrically connected by eutectic bonding using the solder pattern.

A display device according to another aspect of the present disclosure comprise a substrate comprising a display area comprising a plurality of subpixels, and one or more non-display areas, a pixel drive circuit disposed on the substrate, a plurality of insulation layers disposed on the pixel drive circuit, a plurality of banks disposed on the plurality of insulation layers, a plurality of micro-LEDs disposed on the plurality of banks and configured to emit white light, a plurality of color filters disposed on the micro-LED in a first group among the plurality of micro-LEDs, and a black matrix disposed on the micro-LED in a second group among the plurality of micro-LEDs.

The plurality of subpixels may comprise a first subpixel, a second subpixel, and a third subpixel, the plurality of banks are respectively disposed in the first subpixel, the second subpixel, and the third subpixel, the micro-LEDs in the first group are respectively disposed on the plurality of banks, and the micro-LEDs in the second group are respectively disposed on the plurality of banks.

The micro-LEDs in the first group may be normal micro-LEDs, and at least some of the micro-LEDs in the second group may be defective micro-LEDs.

The black matrix may comprise a plurality of opening portions disposed in the micro-LEDs in the first group, and the plurality of color filters may be disposed in the plurality of opening portions.

The plurality of color filters may comprises a first color filter disposed in the first subpixel, a second color filter disposed in the second subpixel, and a third color filter disposed in the third subpixel.

The first color filter may be disposed to extend on the micro-LED in the second group and the black matrix disposed in the first subpixel, the second color filter may be disposed to extend on the micro-LED in the second group and the black matrix disposed in the second subpixel, and the third color filter may be disposed to extend on the micro-LED in the second group and the black matrix disposed in the third subpixel.

The display device may further comprise, a plurality of first electrodes disposed between the plurality of micro-LEDs and the plurality of banks and connected to the plurality of micro-LEDs, and a second electrode disposed between the plurality of micro-LEDs, the black matrix, and the plurality of color filters and connected to the plurality of micro-LEDs.

The display device may further comprise an optical layer disposed on the plurality of insulation layers and configured to surround the plurality of banks and the plurality of micro-LEDs.

The optical layer may be disposed below the second electrode, the black matrix, and the plurality of color filters.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device comprising:
a substrate;
a pixel drive circuit on the substrate;
a bank on the pixel drive circuit;
a plurality of micro-LEDs on the bank, the plurality of micro-LEDs electrically connected to the pixel drive circuit;
a color filter on one of the plurality of micro-LEDs; and
a black matrix on another one of the plurality of micro-LEDs.

2. The display device of claim 1, wherein the plurality of micro-LEDs are white micro-LEDs.

3. The display device of claim 1, wherein the black matrix comprises an opening portion through which the other one of the plurality of micro-LEDs is exposed.

4. The display device of claim 3, wherein the color filter is in the opening portion.

5. The display device of claim 1, wherein the color filter extends to the black matrix and overlaps another micro-LED from the plurality of micro-LEDs.

6. The display device of claim 1, wherein a top surface of the color filter is higher than a top surface of the black matrix.

7. The display device of claim 1, further comprising:
a plurality of first electrodes on the bank, the plurality of first electrodes connected to the plurality of micro-LEDs; and
a second electrode between the plurality of micro-LEDs, the black matrix, and the color filter, the second electrode connected to the plurality of micro-LEDs.

8. The display device of claim 7, wherein the second electrode is flat.

9. The display device of claim 7, further comprising:
an optical layer that surrounds side surfaces of the plurality of micro-LEDs and is below the second electrode.

10. The display device of claim 1, wherein the plurality of micro-LEDs each comprise:
an anode electrode;
a first semiconductor layer on the anode electrode;
an active layer on the first semiconductor layer;
a second semiconductor layer on the active layer; and
a cathode electrode on the second semiconductor layer.

11. The display device of claim 10, further comprising:
a first electrode below the plurality of micro-LEDs, the first electrode electrically connecting the pixel drive circuit and the anode electrode of each of the plurality of micro-LEDs; and
a solder pattern between the first electrode and the anode electrode,
wherein the first electrode and the anode electrode are electrically connected using the solder pattern.

12. A display device comprising:
a substrate comprising a display area comprising a plurality of subpixels and one or more non-display areas;
a pixel drive circuit on the substrate;
a plurality of insulation layers on the pixel drive circuit;
a plurality of banks on the plurality of insulation layers;
a plurality of micro-LEDs on the plurality of banks, the plurality of micro-LEDs configured to emit white light;
a plurality of color filters on a micro-LED in a first group among the plurality of micro-LEDs; and
a black matrix on a micro-LED in a second group among the plurality of micro-LEDs.

13. The display device of claim 12, wherein the plurality of subpixels comprise a first subpixel, a second subpixel, and a third subpixel, the plurality of banks are respectively disposed in the first subpixel, the second subpixel, and the third subpixel, micro-LEDs in the first group are respectively disposed on the plurality of banks, and micro-LEDs in the second group are respectively disposed on the plurality of banks.

14. The display device of claim 13, wherein the micro-LEDs in the first group are normal micro-LEDs and at least some of the micro-LEDs in the second group are defective micro-LEDs.

15. The display device of claim 13, wherein the black matrix comprises a plurality of opening portions in the micro-LEDs in the first group and the plurality of color filters are in the plurality of opening portions.

16. The display device of claim 13, wherein the plurality of color filters comprises:
a first color filter in the first subpixel;
a second color filter in the second subpixel; and
a third color filter in the third subpixel.

17. The display device of claim 16, wherein the first color filter extends on the micro-LED in the second group and the black matrix in the first subpixel, the second color filter extends on the micro-LED in the second group and the black matrix in the second subpixel, and the third color filter extends on the micro-LED in the second group and the black matrix in the third subpixel.

18. The display device of claim 13, further comprising:
a plurality of first electrodes between the plurality of micro-LEDs and the plurality of banks, the plurality of first electrodes connected to the plurality of micro-LEDs; and
a second electrode between the plurality of micro-LEDs, the black matrix, and the plurality of color filters, the second electrode connected to the plurality of micro-LEDs.

19. The display device of claim 18, further comprising:
an optical layer on the plurality of insulation layers, the optical layer surrounding the plurality of banks and the plurality of micro-LEDs.

20. The display device of claim 19, wherein the optical layer is below the second electrode, the black matrix, and the plurality of color filters.
